(19) United States
(12) Patent Application Publication
(10) Pub. No.: US 2024/0191030 A1
(43) Pub. Date: Jun. 13, 2024

(54) RESIN COMPOSITION, CURED OBJECT, RESIN SHEET, PREPREG, METAL-CLAD LAMINATE, MULTILAYERED PRINTED WIRING BOARD, SEALING MATERIAL, FIBER-REINFORCED COMPOSITE MATERIAL, ADHESIVE, AND SEMICONDUCTOR DEVICE

(71) Applicant: NIPPON KAYAKU KABUSHIKI KAISHA, Tokyo (JP)

(72) Inventors: Kazuyoshi YAMAMOTO, Tokyo (JP); Takahumi MIZUGUCHI, Tokyo (JP); Eri YOSHIZAWA, Tokyo (JP); Mao TAKEDA, Tokyo (JP)

(73) Assignee: NIPPON KAYAKU KABUSHIKI KAISHA, Tokyo (JP)

(21) Appl. No.: 18/277,577

(22) PCT Filed: Nov. 4, 2021
(86) PCT No.: PCT/JP2021/040619

§ 371 Date: Aug. 16, 2023

(30) Foreign Application Priority Data
Mar. 25, 2021 (JP) 2021-052293

(51) Int. Cl. C08G 73/12; C08J 5/18; C08J 5/24; C08K 5/5397; C09J 179/08; H05K 1/03

(52) U.S. Cl. CPC C08G 73/12; C08J 5/18; C08J 5/24; C08K 5/5397; C09J 179/085; H05K 1/0346; C08J 2379/08; H05K 2201/0154

(57) ABSTRACT

This resin composition comprises a bismaleimide compound (A) including a constituent unit represented by formula (1) and containing maleimide groups at both ends of the molecular chain, at least one resin or compound (B) selected from the group consisting of maleimide compounds other than the bismaleimide compound (A), cyanic acid ester compounds, benzoxazine compounds, epoxy resins, carbodiimide compounds, and compounds having an ethylenically unsaturated group, and a photocuring initiator (C). In formula (1), R1 represents a linear or branched C1-C16 alkylene group or a linear or branched C2-C16 alkenylene group, R2 represents a linear or branched C1-C16 alkylene group or a linear or branched C2-C16 alkenylene group, the R3 moieties each independently represent a hydrogen atom, a linear or branched C1-C16 alkyl group, or a linear or branched C2-C16 alkenyl group, n₁ each independently indicates an integer of 1-4, and n₂ each independently indicates an integer of 1-4.

### TECHNICAL FIELD

The present invention relates to a resin composition, a cured object, a resin sheet, a prepreg, a metal-clad laminate, a multilayered printed wiring board, a sealing material, a fiber-reinforced composite material, an adhesive and a semiconductor device.

### BACKGROUND ART

In recent years, the development of higher-performance materials has been required, particularly with progress in the field of advanced materials. For example, for applications such as large-capacity communication instruments, antenna modules for smartphones, materials for cable systems for laptops, materials for millimeter-wave radar and auto brake device-related instruments for vehicles, demands for better dielectric characteristics, heat resistance, low stress, water resistance, adhesiveness and the like are increasing for electronic circuit substrates.

Along with reducing the size and increasing the density of multilayered printed wiring boards, attempts to reduce the thickness of laminates used in multilayered printed wiring boards are being actively performed. Along with reducing the thickness, reducing the thickness of an insulating layer is also required, and there is a demand for resin sheets that do not contain glass cloth. A resin composition used as a material of the insulating layer is mainly a thermally curable resin, and drilling holes for obtaining electrical continuity between insulating layers is generally performed by laser processing.

On the other hand, drilling holes by laser processing has a problem that the processing time becomes longer as the substrate has a higher density with a larger number of holes. Therefore, in recent years, there has been a demand for a resin sheet that can be drilled all at once during exposure and a developing process by using a resin composition in which an exposed part is cured (exposure process) with emission of a light beam or the like and an unexposed part can be removed (developing process).

As an exposure method, a method of exposing through a photo mask using a mercury lamp as a light source is used, and there is a demand for a material that can be suitably exposed to the light source of the mercury lamp. In this exposure method using a mercury lamp as a light source, ghi-mixed lines (a g line at a wavelength of 436 nm, an h line at a wavelength of 405 nm, and an i line at a wavelength of 365 nm) are used, and a general-purpose photocuring initiator can be selected. In addition, in recent years, as an exposure method, a direct drawing exposure method in which drawing is directly performed on a photosensitive resin composition layer without using a photo mask based on digital pattern data has been introduced. Compared to the exposure method through a photo mask, in this direct drawing exposure method, the alignment accuracy is better and a higher-density pattern can be obtained, and thus this method is particularly introduced for substrates for which a high-density wiring formation is required. In the light source, monochromatic light such as a laser is used, and particularly, a light source with a wavelength of 405 nm (h line) is used in a digital micro mirror device (DMD) type device that can form a high-definition resist pattern.

In the photosensitive resin composition used for the laminate and resin sheet, a compound having an ethylenically unsaturated group such as (meth)acrylate is used in order to enable rapid curing in the exposure process.

For example, Patent Literature 1 describes a photosensitive thermosetting resin composition containing a carboxyl-modified epoxy (meth)acrylate resin obtained by reacting a bisphenol type epoxy resin and (meth)acrylic acid and then reacting it with an acid anhydride, a biphenyl type epoxy resin, a photocuring initiator, and a diluent.

In addition, Patent Literature 2 describes a resin composition containing a photocurable binder polymer, a photopolymerization compound having an ethylenically unsaturated bond, a photopolymerization (curing) initiator, a sensitizer, and a bisallylnadic imide compound and a bismaleimide compound as a thermosetting agent.

Patent Literature 3 describes, as a photosensitive resin composition used for laminates and resin sheets, a resin composition containing a bismaleimide compound (curable resin) and a photoradical polymerization initiator (curing agent).

### CITATION LIST

### Patent Literature

### [Patent Literature 1]

Japanese Patent Laid-Open No. 2005-62450

### [Patent Literature 2]

Japanese Patent Laid-Open No. 2010-204298

### [Patent Literature 3]

WO2018/56466A1

### SUMMARY OF INVENTION

### Technical Problem

However, a cured object using a conventional (meth)acrylate resin does not exhibit sufficient physical properties, and there is a limit to forming excellent protective films and interlayer insulating layers.

There is a description that the cured object obtained from the resin composition described in Patent Literature 1 has excellent flexibility and bending resistance as a solder resist and also has excellent heat resistance, but there are problems that there is no specific value for heat resistance, and heat resistance and thermal stability are poor when used as an interlayer insulating layer.

Although use of a bismaleimide compound is described in Patent Literature 2, it is described as a thermosetting agent, and (meth)acrylate is used as a photopolymerizable compound. Therefore, there is a problem that heat resistance and thermal stability are poor when used as an interlayer insulating layer.

In Patent Literature 3, a bismaleimide compound is used as a curable resin, but since a maleimide compound generally has poor light transmittance, if a maleimide compound is contained, a sufficient amount of light does not reach a photocuring initiator, the photocuring initiator is less likely to produce radicals, and the reactivity is very low. Thus, in Patent Literature 3, the maleimide compound is cured by performing additional heating before development, but a high-definition resist pattern cannot be obtained due to heating. In addition, Patent Literature 3 does not describe use of active energy rays having a wavelength of 405 nm (h line) as a light source that can perform emission at all.

Therefore, the present invention has been made in view of the above problems, and provides a resin composition which, when used in a multilayered printed wiring board, has excellent photocurability and forms a cured object having excellent heat resistance, thermal stability and insulation reliability in a well-balanced manner, a resin sheet using the same, a multilayered printed wiring board, and a semiconductor device.

### Solution to Problem

The inventors found that the above problems can be addressed by using a resin composition containing a specific bismaleimide compound (A), a specific resin or compound (B), and a photocuring initiator (C), and completed the present invention.

That is, the present invention includes the following contents.

[1] A resin composition including a bismaleimide compound (A) including a constituent unit represented by the following Formula (1) and maleimide groups at both ends of a molecular chain;
at least one resin or compound (B) selected from the group consisting of a maleimide compound other than the bismaleimide compound (A), a cyanic acid ester compound, a benzoxazine compound, an epoxy resin, a carbodiimide compound, and a compound having an ethylenically unsaturated group; and
a photocuring initiator (C):

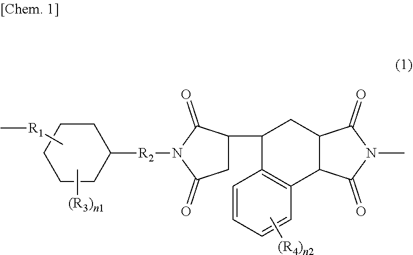

(in Formula (1), R₁ indicates a linear or branched C1-C16 alkylene group or a linear or branched C2-C16 alkenylene group. R₂ indicates a linear or branched C1-C16 alkylene group or a linear or branched C2-C16 alkenylene group. R₃'s each independently indicate a hydrogen atom, a linear or branched C1-C16 alkyl group, or a linear or branched C2-C16 alkenyl group. R4's each independently indicate a hydrogen atom, a linear or branched C1-C6 alkyl group, a halogen atom, a hydroxy group or a linear or branched C1-C6 alkoxy group. n₁'s each independently indicate an integer of 1 to 4. n₂'s each independently indicate an integer of 1 to 4).
[2] The resin composition according to [1], wherein the photocuring initiator (C) contains a compound represented by the following Formula (2).

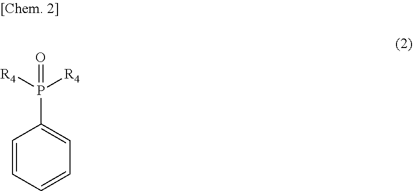

(in Formula (2), R₄'s each independently indicate a substituent or phenyl group represented by the following Formula (3)).

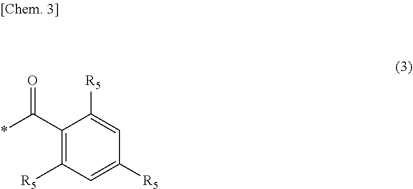

(in Formula (3), -* indicates a bond, and R₅'s each independently indicate a hydrogen atom or a methyl group).
[3] The resin composition according to any one of [1] to [2],
wherein the content of the bismaleimide resin represented by General Formula (1) with respect to a total amount of 100 parts by mass of the bismaleimide compound (A), the resin or compound (B) and the photocuring initiator (C) is 5 to 99.4 parts by mass.
   [4] The resin composition according to any one of [1] to [3], further including a filling material.
   [5] A cured object including the resin composition according to any one of [1] to [3].
   [6] A resin sheet including a support and a resin layer that is disposed on one surface or both surfaces of the support, wherein the resin layer contains the resin composition according to any one of [1] to [3].
   [7] The resin sheet according to [6],
wherein the resin layer has a thickness of 1 to 50 μm.
   [8] A prepreg including a substrate and the resin composition according to any one of [1] to [4] that is impregnated into or applied to the substrate.
   [9] A metal-clad laminate including a layer containing at least one selected from the group consisting of the resin sheet according to [7] and the prepreg according to [8] and a metal foil that is provided on one surface or both surfaces of the layer, wherein the layer contains a cured object of the resin composition.
   [10] A multilayered printed wiring board including an insulating layer and a conductor layer that is formed on one surface or both surfaces of the insulating layer, wherein the insulating layer contains the resin composition according to any one of [1] to [4].
   [11] A sealing material including the resin composition according to any one of [1] to [4].
   [12] A fiber-reinforced composite material including the resin composition according to any one of [1] to [4] and a reinforcing fiber.
   [13] An adhesive including the resin composition according to any one of [1] to [4].
   [14] A semiconductor device including the resin composition according to any one of [1] to [4].

### Advantageous Effects of Invention

According to the present invention, it is possible to provide a resin composition which, when used in a multilayered printed wiring board, has excellent photocurability and form a cured object having excellent heat resistance, thermal stability and insulation reliability in a well-balanced manner, a resin sheet using the same, a multilayered printed wiring board, and a semiconductor device.

### DESCRIPTION OF EMBODIMENTS

Hereinafter, an embodiment (hereinafter referred to as the “present embodiment”) for implementing the present invention will be described in detail. The following present embodiment is only an example for explaining the present invention, and the present invention is not limited to the following content. The present invention can be appropriately modified and implemented without the scope of the present invention.

Here, in this specification, “(meth)acryloxy” refers to both “acryloxy” and a corresponding “methacryloxy,” “(meth)acrylate” means both “acrylate” and a corresponding “methacrylate,” and “(meth)acrylic” means both “acrylic” and a corresponding “methacrylic.”

### Resin Composition

The resin composition of the present embodiment contains a specific bismaleimide compound (A) (also referred to as a “component (A)”), at least one resin or compound (B) (also referred to as a “component (B)” or “resin or compound (B)”) selected from the group consisting of a maleimide compound other than the bismaleimide compound (A), a cyanic acid ester compound, a benzoxazine compound, an epoxy resin, a carbodiimide compound, and a compound having an ethylenically unsaturated group, and a photocuring initiator (C) (also referred to as a “component (C)”). Hereinafter, the components will be described.

### Bismaleimide Compound (A)

The resin composition contains the bismaleimide compound (A) (also referred to as a component (A)). The bismaleimide compound (A) includes a constituent unit represented by Formula (1) and maleimide groups at both ends of a molecular chain.

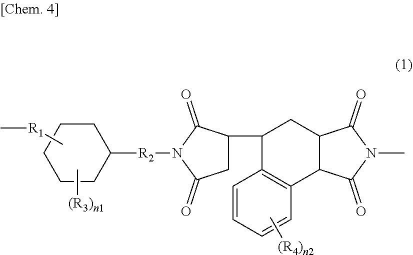

In Formula (1), R₁ indicates a linear or branched C1-C16 alkylene group or a linear or branched C2-C16 alkenylene group. R₂ indicates a linear or branched C1-C16 alkylene group or a linear or branched C2-C16 alkenylene group. R₃'s each independently indicate a hydrogen atom, a linear or branched C1-C16 alkyl group, or a linear or branched C2-C16 alkenyl group. n₁'s each independently indicate an integer of 1 to 4. n₂'s each independently indicate an integer of 1 to 4.

Generally, since the maleimide compound has poor light transmittance, when the resin composition contains the maleimide compound, a sufficient amount of light does not reach the photocuring initiator dispersed in the resin composition, and the photocuring initiator is less likely to produce radicals. Therefore, generally, a photoradical reaction of the maleimide compound is unlikely to proceed, and even if a radical polymerization or dimerization reaction of the maleimide alone proceeds, the reactivity is very low. However, since the bismaleimide compound (A) includes a constituent unit represented by Formula (1), it has very excellent light transmittance. Therefore, a sufficient amount of light reaches the photocuring initiator, a photoradical reaction of the maleimide occurs efficiently, and the bismaleimide compound (A), together with the resin or compound (B) to be described below and the photocuring initiator (C), can be photocured using various active energy rays.

In the present embodiment, when a chloroform solution containing 1 mass % of the bismaleimide compound (A) is prepared, and the transmittance of the chloroform solution containing 1 mass % of the bismaleimide compound (A) is measured using active energy rays having a wavelength of 365 nm (i line), the transmittance is 5% or more, and very excellent light transmittance is exhibited. In addition, when the transmittance of the chloroform solution containing 1 mass % of the bismaleimide compound (A) is measured using active energy rays having a wavelength of 405 nm (h line) (ray), the transmittance is 5% or more, and very excellent light transmittance is exhibited. Therefore, for example, when a printed wiring board having a high-density and high-definition wiring form (pattern) is produced using a direct drawing exposure method, even when active energy rays having a wavelength of 405 nm (h line) are used, a photoradical reaction of maleimide occurs efficiently. The transmittance at a wavelength of 365 nm (i line) is preferably 8% or more and more preferably 10% or more because better light transmittance is exhibited. The transmittance at a wavelength of 405 nm (h line) is preferably 8% or more and more preferably 10% or more because a printed wiring board having a higher-density and higher-definition wiring form (pattern) can be produced. The upper limits of the transmittance at a wavelength of 365 nm (i line) and the transmittance at a wavelength of 405 nm (h line) are, for example, 99.9% or less.

Generally, when rays with a longer wavelength are used, the photocuring initiator tends to have lower absorbance. For example, when active energy rays having a wavelength of 405 nm (h line) are used, since the light with this wavelength has a relatively long wavelength, it is not absorbed by a general photocuring initiator, and polymerization does not proceed unless a photocuring initiator that can appropriately absorb this light and produce radicals is used. Therefore, when the absorbance of a chloroform solution containing 0.01 mass % of the photocuring initiator (C) as the photocuring initiator to be described below (C) is measured, it is preferable to use a photocuring initiator that exhibits very excellent absorption for light with a wavelength of 405 nm (h line) such as an absorbance of 0.1 or more.

Since the bismaleimide compound (A) has excellent light transmittance as described above, for example, even if active energy rays having a wavelength of 365 nm or active energy rays having a wavelength of 405 nm are used, a sufficient amount of light reaches the photocuring initiator, a radical reaction using radicals produced from the photocuring initiator proceeds, and photocuring can be performed even in a composition containing a large amount of the bismaleimide compound (A). Therefore, the resin composition of the present embodiment has excellent photocurability.

On the other hand, since the bismaleimide compound (A) has a rigid imide ring even after photocuring, it has high heat resistance and thermal stability, but wrinkles occur when a cured object obtained by photocuring a bismaleimide compound is additionally cured by heating in a post-baking process or the like that is performed after the exposure process is completed or after the developing process is completed. Therefore, the cured object obtained by homopolymerizing the bismaleimide compound (A) is not suitable for applications in multilayered printed wiring boards. However, when the bismaleimide compound (A) is blended together with the resin or compound (B) to be described below and the photocuring initiator (C), it is possible to achieve higher heat resistance and thermal stability while maintaining excellent photocurability and insulation reliability. Therefore, the cured object obtained from the resin composition of the present embodiment has excellent heat resistance, thermal stability, and insulation reliability, and according to the present embodiment, a protective film and an insulating layer can be suitably formed on a multilayered printed wiring board and a semiconductor device.

The mass average molecular weight of the bismaleimide compound (A) is preferably 100 to 6,000 and more preferably 300 to 5,500 because a suitable viscosity can be obtained and an increase in viscosity of the varnish can be reduced. Here, the “mass average molecular weight” is a mass average molecular weight in terms of polystyrene standards according to a gel permeation chromatography (GPC) method.

Next, the structure of the bismaleimide compound (A) will be described.

In the Formula (1) of the bismaleimide compound (A), R₁ indicates a linear or branched C1-C16 alkylene group or a linear or branched C2-C16 alkenylene group. R₁ is preferably a linear or branched alkylene group and more preferably a linear alkylene group because a suitable viscosity can be obtained and an increase in viscosity of the varnish controlled.

The number of carbon atoms in the alkylene group is preferably 2 to 14 and more preferably 4 to 12 because a more suitable viscosity can be obtained and an increase in viscosity of the varnish can be better controlled.

Examples of linear or branched alkylene groups include a methylene group, ethylene group, propylene group, 2,2-dimethylpropylene group, butylene group, pentylene group, hexylene group, heptylene group, octylene group, nonylene group, decylene group, dodecylene group, undecylene group, tridecylene group, tetradecylene group, pentadecylene group, hexadecylene group, neopentylene group, dimethylbutylene group, methylhexylene group, ethylhexylene group, dimethylhexylene group, trimethylhexylene group, methylheptylene group, dimethylheptylene group, trimethylheptylene group, tetramethylheptylene group, ethylheptylene group, methyloctylene group, methylnonylene group, methyldecylene group, methyldodecylene group, methylundecylene group, methyltridecylene group, methyltetradecylene group, and methylpentadecylene group.

The number of carbon atoms in the alkenylene group is preferably 2 to 14 and more preferably 4 to 12 because a more suitable viscosity can be obtained and an increase in viscosity of the varnish can be better controlled.

Examples of linear or branched alkenylene groups include a vinylene group, 1-methyl vinylene group, arylene group, propenylene group, isopropenylene group, 1-butenylene group, 2-butenylene group, 1-pentenylene group, 2-pentenylene group, isopentenylene group, cyclopentenylene group, cyclohexenylene group, and dicyclopentadienylene group.

In Formula (1), R₂ indicates a linear or branched C1-C16 alkylene group or a linear or branched C2-C16 alkenylene group. R₂ is preferably a linear or branched alkylene group and more preferably a linear alkylene group because a suitable viscosity can be obtained and an increase in viscosity of the varnish controlled.

The number of carbon atoms in the alkylene group is preferably 2 to 14 and more preferably 4 to 12 because a more suitable viscosity can be obtained and an increase in viscosity of the varnish can be better controlled.

As the linear or branched alkylene group, R₁ can be referred to.

The number of carbon atoms in the alkenylene group is preferably 2 to 14 and more preferably 4 to 12 because a more suitable viscosity can be obtained and an increase in viscosity of the varnish can be better controlled.

As the linear or branched alkenylene group, R₁ can be referred to.

In Formula (1), R₁ and R₂ may be the same as or different from each other, and are preferably the same because the bismaleimide compound (A) can be more easily synthesized.

In Formula (1), R₃'s each independently indicate a hydrogen atom, a linear or branched C1-C16 alkyl group, or a linear or branched C2-C16 alkenyl group. R₃'s each independently preferably indicate a hydrogen atom or a linear or branched C1-C16 alkyl group because a suitable viscosity can be obtained and an increase in viscosity of the varnish controlled, and more preferably, 1 to 4 groups (R₃) among R₃'s are a linear or branched C1-C16 alkyl group, and the remaining groups (R₃) are a hydrogen atom, and still more preferably, 1 to 3 groups (R₃) among R₃'s are a linear or branched C1-C16 alkyl group, and the remaining groups (R₃) are a hydrogen atom.

The number of carbon atoms in the alkyl group is preferably 2 to 14 and more preferably 4 to 12 because a more suitable viscosity can be obtained and an increase in viscosity of the varnish can be better controlled.

Examples of linear or branched alkyl groups include a methyl group, ethyl group, n-propyl group, isopropyl group, 1-ethyl propyl group, n-butyl group, 2-butyl group, isobutyl group, tert-butyl group, n-pentyl group, 2-pentyl group, tert-pentyl group, 2-methylbutyl group, 3-methylbutyl group, 2,2-dimethylpropyl group, n-hexyl group, 2-hexyl group, 3-hexyl group, n-heptyl group, n-octyl group, 2-methylpentyl group, 3-methylpentyl group, 4-methylpentyl group, 2-methylpentan-3-yl group, and n-nonyl group.

The number of carbon atoms in the alkenyl group is preferably 2 to 14 and more preferably 4 to 12 because a more suitable viscosity can be obtained and an increase in viscosity of the varnish can be better controlled.

Examples of linear or branched alkenyl groups include a vinyl group, allyl group, 4-pentenyl group, isopropenyl group, isopentenyl group, 2-heptenyl group, 2-octenyl group, and 2-nonenyl group.

In Formula (1), R₄'s each independently indicate a hydrogen atom, a linear or branched C1-C6 alkyl group, halogen atom, a hydroxy group or a linear or branched C1-C6 alkoxy group. R₄ is preferably a hydrogen atom or a linear or branched C1-C6 alkyl group in consideration of dielectric characteristics.

The number of carbon atoms in the alkyl group is preferably 1 to 6 and more preferably 1 to 3 because a more suitable viscosity can be obtained.

Examples of linear or branched alkyl groups include a methyl group, ethyl group, n-propyl group, and isopropyl group.

Examples of halogen atoms include fluorine atoms, chlorine atoms, bromine atoms, and iodine atoms.

The number of carbon atoms in the alkoxy group is preferably 1 to 6, and more preferably 1 to 3 because a more suitable viscosity can be obtained.

Examples of linear or branched alkoxy groups include a methoxy group, ethoxy group, n-propoxy group, and isopropoxy group.

In Formula (1), n₁'s each independently indicate an integer of 1 to 4. n₂'s each independently indicate an integer of 1 to 4.

The bismaleimide compound (A) has maleimide groups at both ends of a molecular chain. In the present embodiment, “both ends” means ends at both sides in the molecular chain of the bismaleimide compound (A), and for example, it means that, when the structural unit represented by Formula (1) is at the end of the molecular chain of the bismaleimide compound (A), the maleimide group is provided at the end of the molecular chain of R₁, at the end of the molecular chain at the N atom of the maleimide ring or both ends. The bismaleimide compound (A) may have maleimide groups at positions other than both ends of the molecular chain.

In the present embodiment, the maleimide group is represented by Formula (4), and an N atom is bonded to the molecular chain of Formula (1). In addition, the maleimide groups bonded to Formula (1) may all be the same as or different from each other, and maleimide groups at both ends of a molecular chain are preferably the same.

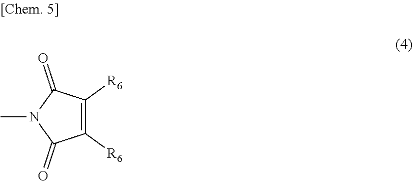

In Formula (4), R₆'s each independently indicate a hydrogen atom or a linear or branched C1-C4 alkyl group. Both R₆ are preferably hydrogen atoms in consideration of suitable photocuring.

The number of carbon atoms in the alkyl group is preferably 1 to 3 and more preferably 1 to 2 in consideration of suitable curing.

As the linear or branched alkyl group, R₃ can be referred to.

Examples of the bismaleimide compound (A) include bismaleimide compounds represented by Formula (5). These can be used alone or two or more thereof can be appropriately used in combination.

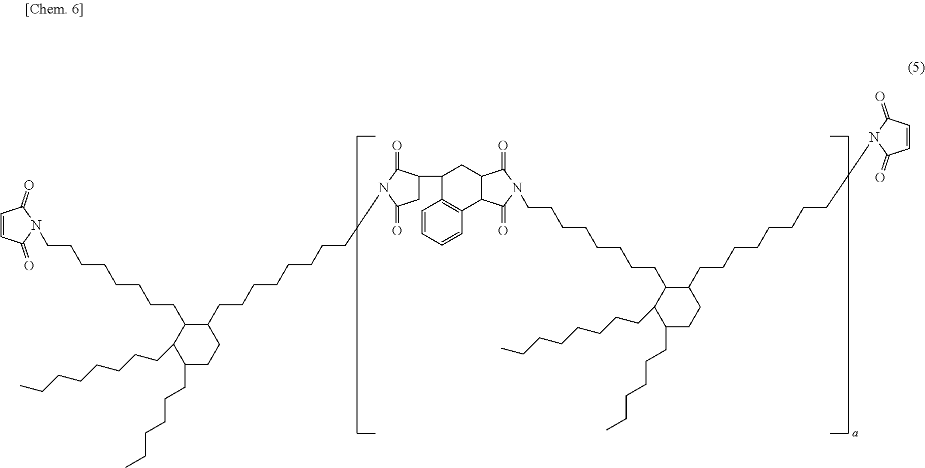

In Formula (5), a indicates an integer of 1 to 10. a is preferably an integer of 1 to 6 because a more suitable viscosity can be obtained and an increase in viscosity of the varnish can be better controlled.

In the resin composition of the present embodiment, the content of the bismaleimide compound (A) with respect to a total of 100 parts by mass of the bismaleimide compound (A), the resin or compound (B) to be described below and the photocuring initiator (C) to be described below is preferably 5 to 99.4 parts by mass, more preferably 8 to 98 parts by mass, and still more preferably 13 to 93 parts by mass because a cured object mainly composed of a bismaleimide compound can be obtained, and it is possible to improve photocurability, heat resistance and dielectric characteristics in a well-balanced manner.

The bismaleimide compounds (A) can be used alone or two or more thereof can be appropriately used in combination.

### Method of Producing Bismaleimide Compound (A)

The bismaleimide compound (A) can be produced by a known method. For example, 4-(2,5-dioxotetrahydrofuran-3-yl)-1,2,3,4-tetrahydronaphthalene-1,2-dicarboxylic anhydride, monomers containing diamine, including dimer diamines and the like, and a maleimide compound such as a maleimide anhydride are subjected to a polyaddition reaction at a temperature of generally about 80 to 250° C., and preferably about 100 to 200° C. for generally about 0.5 to 50 hours, and preferably about 1 to 20 hours to obtain a polyadduct, and the polyadduct is then subjected to an imidization reaction, that is, a dehydrative ring-closing reaction, at a temperature of generally about 60 to 120° C., and preferably about 80 to 100° C. for generally about 0.1 to 2 hours, and preferably about 0.1 to 0.5 hours to obtain a bismaleimide compound (A).

Dimer diamines are obtained according to, for example, a reductive amination reaction of dimer acids, and the amination reaction can be performed, for example, by known methods (for example, the method described in Japanese Patent Laid-Open No. H9-12712) such as a reduction method using ammonia and a catalyst. Dimer acids are dibasic acids obtained by dimerizing unsaturated fatty acids according to an intermolecular polymerization reaction or the like. Although it depends on synthesis conditions and purification conditions, in addition to dimer acids, a small amount of monomer acids, trimer acids and the like is generally contained. Although double bonds remain in the obtained molecule after the reaction, in the present embodiment, the dimer acids include a saturated dibasic acid obtained by reducing the number of double bonds present in the molecule according to a hydrogenation reaction. Dimer acids are obtained by, for example, polymerizing unsaturated fatty acids using a Lewis acid and a Bronsted acid as a catalyst. Dimer acids can be produced by a known method (for example, the method described in Japanese Patent Laid-Open No. H9-12712). Examples of unsaturated fatty acids include crotonic acid, myristoleic acid, palmitoleic acid, oleic acid, elaidic acid, vaccenic acid, gadoleic acid, eicosenoic acid, erucic acid, nervonic acid, linoleic acid, pinolenic acid, eleostearic acid, mead acid, dihomo-γ-linolenic acid, eicosatrienoic acid, stearidonic acid, arachidonic acid, eicosatetraenoic acid, adrenic acid, bosseopentaenoic acid, osbond acid, clupanodonic acid, tetracosapentaenoic acid, docosahexaenoic acid, and nisinic acid. The number of carbon atoms in the unsaturated fatty acid is generally 4 to 24, and preferably 14 to 20.

In the production of the bismaleimide compound (A), monomers containing diamine are preferably dissolved or dispersed in a slurry form in advance in an organic solvent, for example, in an inert atmosphere of argon, nitrogen or the like, to form a monomer solution containing diamine. Then, 4-(2,5-dioxotetrahydrofuran-3-yl)-1,2,3,4-tetrahydronaphthalene-1,2dicarboxylic anhydride that has been dissolved or dispersed in a slurry form in an organic solvent or that is in a solid state is preferably added to the monomer solution containing diamine.

Any bismaleimide compound (A) can be obtained by adjusting the number of moles of 4-(2,5-dioxotetrahydrofuran-3-yl)-1,2,3,4-tetrahydronaphthalene-1,2-dicarboxylic anhydride and the number of moles of the total amount of monomers containing diamine and the maleimide compound.

Various known solvents can be used in a polyaddition reaction and an imidization reaction. Examples of solvents include amides such as N,N-dimethylformamide, N,N-dimethylacetamide, and N-methyl-2-pyrrolidone; ketones such as acetone, methyl ethyl ketone, methyl isobutyl ketone, cyclohexanone, and isophorone; esters such as γ-butyrolactone, γ-valerolactone, δ-valerolactone, γ-caprolactone, ε-caprolactone, α-methyl-γ-butyrolactone, ethyl lactate, methyl acetate, ethyl acetate, and butyl acetate; C1-C10 aliphatic alcohols such as methanol, ethanol, and propanol; aromatic group-containing phenols such as phenol and cresol; aromatic group-containing alcohols such as benzyl alcohol; glycol ethers such as glycols such as ethylene glycol and propylene glycol, or glycols thereof, and monoethers or diethers with methanol, ethanol, butanol, hexanol, octanol, benzyl alcohol, phenol, cresol, and the like, or esters of these monoethers; ethers such as dioxane and tetrahydrofuran; cyclic carbonates such as ethylene carbonate and propylene carbonate; aromatic hydrocarbons such as aliphatic hydrocarbon, toluene, and xylene; and aprotic polar solvents such as dimethyl sulfoxide. These solvents can be used alone or two or more thereof can be used in combination as necessary.

In addition, in the imidization reaction, a catalyst is preferably used. As the catalyst, for example, a tertiary amine and a dehydration catalyst can be used. As the tertiary amine, a heterocyclic tertiary amine is preferable, and examples thereof include pyridine, picoline, quinoline, and isoquinoline. Examples of dehydration catalysts include acetic anhydride, propionic anhydride, n-butyric anhydride, benzoic anhydride, and trifluoroacetic anhydride.

Regarding the amount of the catalyst added, for example, preferably, the amount of the imidization agent is about 0.5- to 5.0-fold molar equivalent that of the amide group, and the amount of the dehydration catalyst is 0.5- to 10.0-fold molar equivalent that of the amide group.

After the imidization reaction is completed, this solution may be used as the bismaleimide compound (A) solution, or a poor solvent may be added to the reaction solvent to form the bismaleimide compound (A) into a solid. Examples of poor solvents include water, methyl alcohol, ethyl alcohol, 2-propyl alcohol, ethylene glycol, triethyleneglycol, 2-butyl alcohol, 2-pentyl alcohol, 2-hexyl alcohol, cyclopentyl alcohol, cyclohexyl alcohol, phenol, and t-butyl alcohol.

### Resin or Compound (B)

The resin composition of the present embodiment contains at least one resin or compound (B) (also referred to as a component (B)) selected from the group consisting of maleimide compounds other than the bismaleimide compound (A), a cyanic acid ester compound, a benzoxazine compound, an epoxy resin, a carbodiimide compound, and a compound having an ethylenically unsaturated group. These resins or compounds (B) can be used alone or two or more thereof can be appropriately used in combination according to physical properties and applications of the obtained cured object.

In the present embodiment, when the resin or compound (B) is used together with the bismaleimide compound (A) and the photocuring initiator to be described below, photocurability, heat resistance and thermal stability are excellent. Although the reason for this is not clear, the inventors speculated it to be due to the fact that it is possible to achieve both photocurability and insulation reliability of the bismaleimide compound (A) and heat resistance and thermal stability of the resin or compound (B). In addition, various physical properties of the bismaleimide compound (A) and the resin or compound (B) can be imparted to the obtained cured object. Since the bismaleimide compound (A) has very excellent light transmittance, even if the resin or compound (B) is used, a sufficient amount of light reaches the photocuring initiator, a photoradical reaction of the maleimide occurs efficiently, and photocuring can be performed using various active energy rays. Therefore, for example, even if active energy rays having a wavelength of 365 nm or active energy rays having a wavelength of 405 nm are used, a sufficient amount of light reaches the photocuring initiator, a radical reaction proceeds using radicals produced from the photocuring initiator, and photocuring can occur in a composition containing the resin or compound (B).

The resin or compound (B), together with the bismaleimide compound (A) and the photocuring initiator (C), can be photocured using various active energy rays to obtain a cured object.

In the present embodiment, a N-methylpyrrolidone solution containing 1 mass % of the resin or compound (B) is prepared, and when the transmittance of the N-methylpyrrolidone solution containing 1 mass % of the compound (B) containing one or more carboxy groups is measured using active energy rays having a wavelength of 365 nm (i line), the transmittance is preferably 5% or more. The resin or compound (B) exhibits very excellent light transmittance. In addition, using active energy rays having a wavelength of 405 nm (h line), when the transmittance of the N-methylpyrrolidone solution containing 1 mass % of the resin or compound (B) is measured, the transmittance is preferably 5% or more, and very excellent light transmittance is exhibited in this case. If the resin or compound (B) is used, for example, when a printed wiring board having a high-density and high-definition wiring form (pattern) is produced using a direct drawing exposure method, even when active energy rays having a wavelength of 405 nm (h line) are used, a photoradical reaction of maleimide occurs efficiently. Here, the transmittance at a wavelength of 365 nm (i line) is more preferably 8% or more and still more preferably 10% or more because a resin composition having better photocurability can be obtained. The transmittance at a wavelength of 405 nm (h line) is more preferably 8% or more and still more preferably 10% or more because a resin composition having better photocurability can be obtained. Here, the upper limits of the transmittance at a wavelength of 365 nm (i line) and the transmittance at a wavelength of 405 nm (h line) are, for example, 99.9% or less.

The molecular weight of the resin or compound (B) is preferably 100 to 5,000 because an increase in viscosity of the varnish can be reduced. In addition, the resin or compound (B) is not particularly limited as long as effects of the present invention are exhibited, and the mass average molecular weight is preferably 100 to 50,000 because an increase in viscosity of the varnish can be reduced. Here, in the present embodiment, the “mass average molecular weight” is a mass average molecular weight in terms of polystyrene standards according to a gel permeation chromatography (GPC) method.

In the resin composition, a total content of the resin or compound (B) is preferably 0.5 to 85 parts by mass, more preferably 1 to 84 parts by mass, and still more preferably 5 to 80 parts by mass with respect to a total of 100 parts by mass of the bismaleimide compound (A), the resin or compound (B) and the photocuring initiator to be described below (C) because it is possible to obtain a cured object mainly composed of a bismaleimide compound and photocurability is improved.

### Maleimide Compound Other Than Bismaleimide Compound (A)

In the resin composition, a maleimide compound (B1) (also referred to as a component (B1)) other than the bismaleimide compound (A) can be used. Hereinafter, the maleimide compound (B1) will be described.

The maleimide compound (B-1) is not particularly limited as long as it is a compound other than the maleimide compound (A) and having one or more maleimide groups in the molecule. Specific examples thereof include N-phenyl maleimide, N-cyclohexyl maleimide, N-hydroxy phenyl maleimide, N-anilinophenyl maleimide, N-carboxyphenyl maleimide, N-(4-carboxy-3-hydroxyphenyl)maleimide, 6-maleimide hexanoic acid, 4-maleimide butyric acid, bis(4-maleimide phenyl)methane, 2,2-bis{4-(4-maleimide phenoxy)-phenyl}propane, 4,4-diphenylmethane bismaleimide, bis(3,5-dimethyl-4-maleimide phenyl)methane, bis(3-ethyl-5-methyl-4-maleimide phenyl)methane, bis(3,5-diethyl-4-maleimide phenyl)methane, phenylmethane maleimide, o-phenylene bismaleimide, m-phenylene bismaleimide, p-phenylene bismaleimide, o-phenylene biscitraconimide, m-phenylene biscitraconimide, p-phenylenebiscitraconimide, 2,2-bis(4-(4-maleimide phenoxy)-phenyl)propane, 3,3-dimethyl-5,5-diethyl-4,4-diphenylmethane bismaleimide, 4-methyl-1,3-phenylene bismaleimide, 1,2-bismaleimide ethane, 1,4-bismaleimide butane, 1,5-bismaleimide pentane, 1,5-bismaleimide-2-methylpentane, 1,6-bismaleimide hexane, 1,6-bismaleimido-(2,2,4-trimethyl)hexane, 1,8-bismaleimide-3,6-dioxaoctane, 1,11-bismaleimide-3,6,9-trioxaundecane, 1,3-bis(maleimide methyl)cyclohexane, 1,4-bis(maleimide methyl)cyclohexane, 4,4-diphenyl ether bismaleimide, 4,4-diphenylsulfone bismaleimide, 1,3-bis(3-maleimide phenoxy)benzene, 1,3-bis(4-maleimide phenoxy)benzene, 4,4-diphenylmethanebiscitraconimide, 2,2-bis[4-(4-citraconimidophenoxy)phenyl]propane, bis(3,5-dimethyl-4-citraconimidophenyl)methane, bis(3-ethyl-5-methyl-4-citraconimidophenyl)methane, bis(3,5-diethyl-4-citraconimidophenyl)methane, maleimide compounds represented by the following Formula (6) such as polyphenylmethane maleimide, maleimide compounds represented by the following Formula (7), fluorescein-5-maleimide, prepolymers of these maleimide compounds, and prepolymers of maleimide compounds and amine compounds. These maleimide compounds (B-1) can be used alone or two or more thereof can be appropriately used in combination.

As maleimide compounds represented by the following Formula (6), commercial products can be used, and examples thereof include BMI-2300 (product name, commercially available from Daiwa Fine Chemicals Co., Ltd.). As maleimide compounds represented by the following Formula (7), commercial products can be used, and examples thereof include MIR-3000 (product name, commercially available from Nippon Kayaku Co., Ltd.). As maleimide compounds represented by the following Formula (8), commercial products can be used, and examples thereof include MIR-5,000 (product name, commercially available from Nippon Kayaku Co., Ltd.).

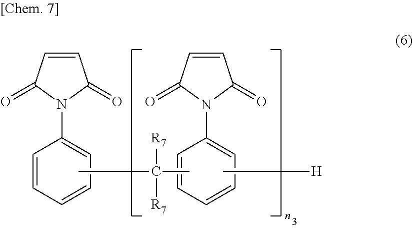

In Formula (6), R₇'s each independently indicate a hydrogen atom or a methyl group. n₃ indicates an integer of 1 or more, preferably an integer of 1 to 10, and more preferably an integer of 1 to 5.

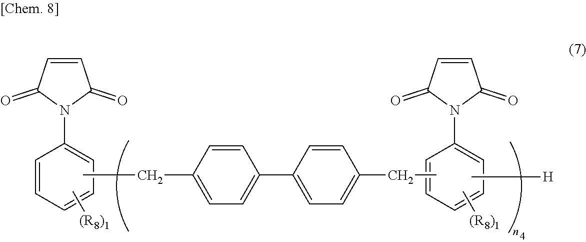

In Formula (7), R₈'s each independently indicate a hydrogen atom or a methyl group. n₄ indicates an integer of 1 or more, and preferably indicates an integer of 1 to 5.

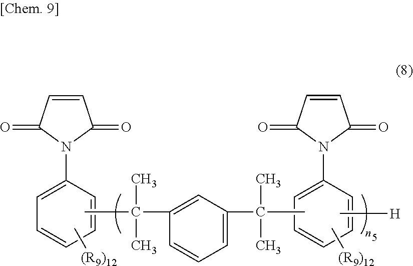

In Formula (8), R₉'s each independently indicate a hydrogen atom, a C1-C5 alkyl group, or a phenyl group, l2's each independently indicate an integer of 1 to 3, and n₅ indicates an integer of 1 to 10.

Examples of C1-C5 alkyl groups include a methyl group, ethyl group, n-propyl group, isopropyl group, n-butyl group, isobutyl group, sec-butyl group, t-butyl group, n-pentyl group, and neopentyl group.

In the present embodiment, in order to efficiently cause a photoradical reaction of the bismaleimide compound (A), a chloroform solution containing 1 mass % of the maleimide compound (B1) is prepared, and when the transmittance of the chloroform solution is measured using active energy rays having a wavelength of 365 nm (i line), the transmittance is preferably a light transmittance of 5% or more. In this case, the transmittance is more preferably 8% or more and still more preferably 10% or more.

In addition, in order to efficiently cause a photoradical reaction of the bismaleimide compound (A), a chloroform solution containing 1 mass % of the maleimide compound (B1) is prepared, and when the transmittance of the chloroform solution is measured using active energy rays having a wavelength of 405 nm (h line), the transmittance is preferably a light transmittance of 5% or more. If the maleimide compound (B1) is used, for example, when a printed wiring board having a high-density and high-definition wiring form (pattern) is produced using a direct drawing exposure method, even when active energy rays having a wavelength of 405 nm (h line) are used, a photoradical reaction of maleimide occurs efficiently. The light transmittance is more preferably 8% or more and still more preferably 10% or more because a resin composition having better photocurability can be obtained.

Examples of maleimide compounds (B-1) include maleimide compounds represented by the following Formula (9), maleimide compounds represented by the following Formula (10), maleimide compounds represented by the following Formula (17), maleimide compounds represented by the following Formula (11), maleimide compounds represented by the following Formula (12), maleimide compounds represented by the following Formula (13), maleimide compounds represented by the following Formula (14), 1,6-bismaleimido-(2,2,4-trimethyl)hexane (maleimide compounds represented by the following Formula (14)), maleimide compounds represented by the following Formula (16), and fluorescein-5-maleimide.

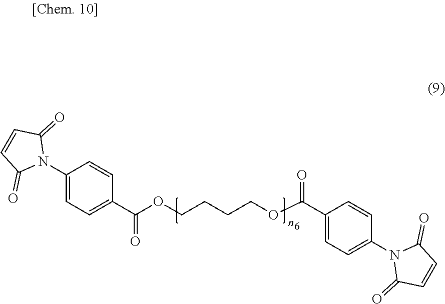

In Formula (9), n₆ (average) is 1 or more, preferably 1 to 21, and more preferably 1 to 16 because excellent photocurability is exhibited.

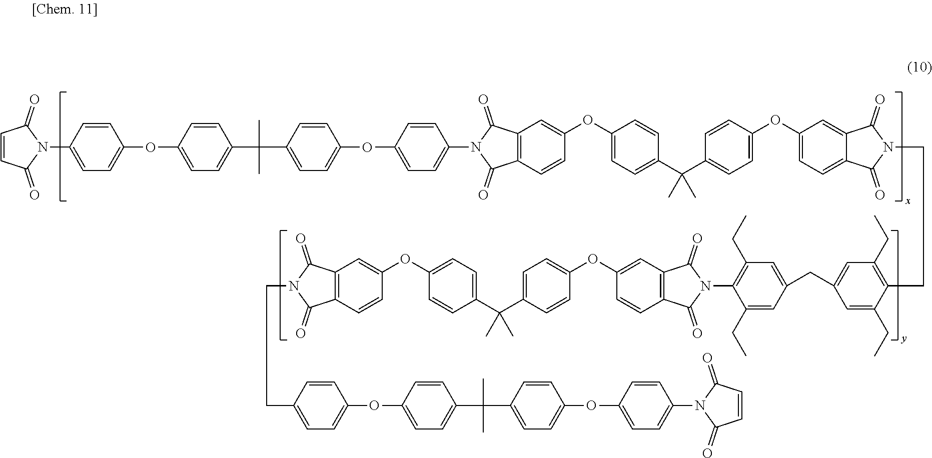

In Formula (10), the number of x is 10 to 35.

In Formula (10), the number of y is 10 to 35.

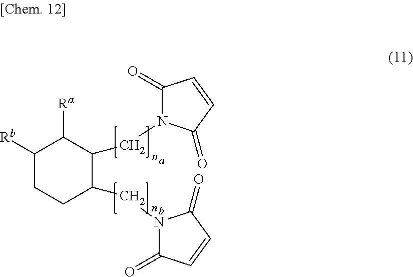

In Formula (11), R^{a} indicates a linear or branched C1-C16 alkyl group or a linear or branched C2-C16 alkenyl group. R^{a} is preferably a linear or branched alkyl group and more preferably a linear alkyl group because excellent photocurability is exhibited.

The number of carbon atoms in the alkyl group is preferably 4 to 12 because excellent photocurability is exhibited.

The number of carbon atoms in the alkenyl group is preferably 4 to 12 because excellent photocurability is exhibited.

As the linear or branched alkyl group, R₃ in the bismaleimide compound (A) can be referred to. Among these, an n-heptyl group, n-octyl group, and n-nonyl group are preferable, and a n-octyl group is more preferable because excellent photocurability is exhibited.

As the linear or branched alkenyl group, R₃ in the bismaleimide compound (A) can be referred to. Among these, a 2-heptenyl group, 2-octenyl group, and 2-nonenyl group are preferable, and a 2-octenyl group is more preferable because excellent photocurability is exhibited.

In Formula (11), R^{b} indicates a linear or branched C1-C16 alkyl group or a linear or branched C2-C16 alkenyl group. R^{b} is preferably a linear or branched alkyl group and more preferably a linear alkyl group because excellent photocurability is exhibited.

The number of carbon atoms in the alkyl group is preferably 4 to 12 because excellent photocurability is exhibited.

The number of carbon atoms in the alkenyl group is preferably 4 to 12 because excellent photocurability is exhibited.

As specific examples of alkyl groups, the alkyl groups for R^{a} can be referred to. Among these, an n-heptyl group, n-octyl group, and n-nonyl group are preferable, and an n-octyl group is more preferable because excellent photocurability is exhibited.

As specific examples of alkenyl groups, the alkenyl groups for R^{a} can be referred to. Among these, a 2-heptenyl group, 2-octenyl group, and 2-nonenyl group are preferable, and a 2-octenyl group is more preferable because excellent photocurability is exhibited.

In Formula (11), the number of nₐ is 1 or more, preferably 2 to 16, and more preferably 3 to 14 because excellent photocurability is exhibited.

In Formula (11), the number of n_{b} is 1 or more, preferably 2 to 16, and more preferably 3 to 14 because excellent photocurability is exhibited.

The numbers of nₐ and n_{b} may be the same as or different from each other.

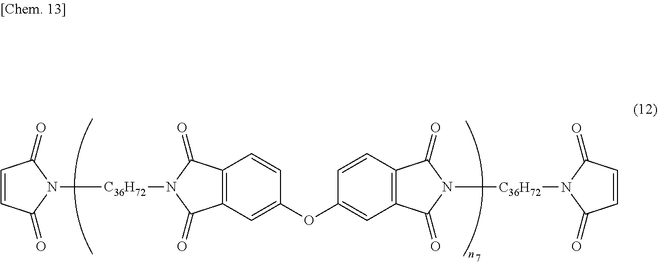

In Formula (12), n₇ (average) is 0.5 or more, preferably 0.8 to 10, and more preferably 1 to 8 because excellent photocurability is exhibited.

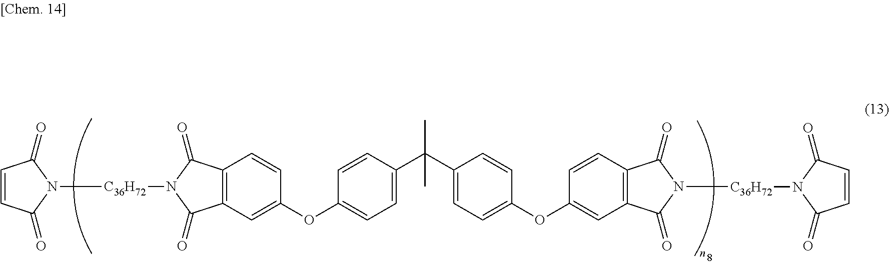

In Formula (13), n₈ indicates an integer of 1 or more, and preferably indicates an integer of 1 to 10.

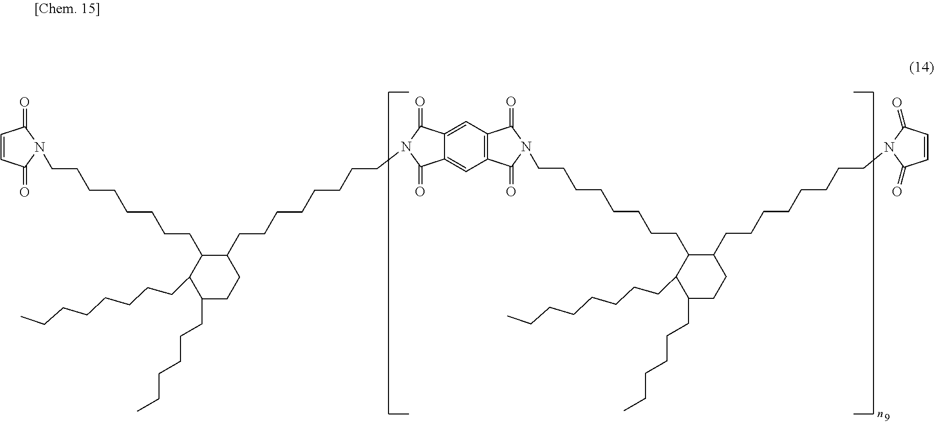

In Formula (14), n₉ indicates an integer of 1 or more, and preferably indicates an integer of 1 to 10.

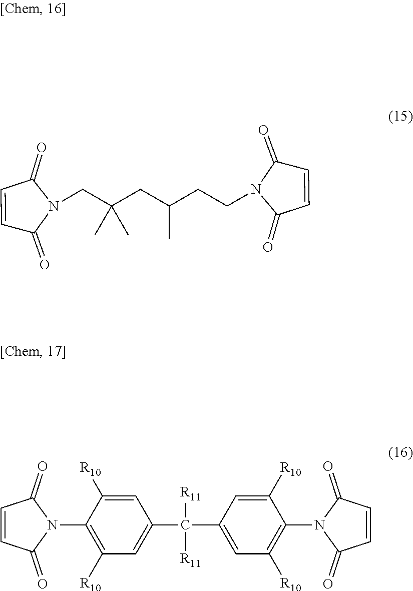

In Formula (16), R₁₀'s each independently indicate a hydrogen atom, a methyl group or an ethyl group, and R₁₁'s each independently indicate a hydrogen atom or a methyl group.

As the maleimide compound (B-1), commercial products can also be used.

Examples of maleimide compounds represented by Formula (9) include BMI-1000P (product name, in Formula (9), n₆=13.6 (average), commercially available from K⋅I Chemical Industry Co., Ltd.), BMI-650P (product name, in Formula (9), n₆=8.8 (average), commercially available from K⋅I Chemical Industry Co., Ltd.), BMI-250P (product name, in Formula (9), n₆=3 to 8 (average), commercially available from K⋅I Chemical Industry Co., Ltd.), and CUA-4 (product name, in Formula (9), n₆=1, commercially available from K⋅I Chemical Industry Co., Ltd.).

Examples of maleimide compounds represented by Formula (10) include BMI-6100 (product name, in Formula (10), x=18, y=18, commercially available from Designer Molecules Inc.).

Examples of maleimide compounds represented by Formula (11) include BMI-689 (product name, the following Formula (17), functional group equivalent: 346 g/eq., commercially available from Designer Molecules Inc.).

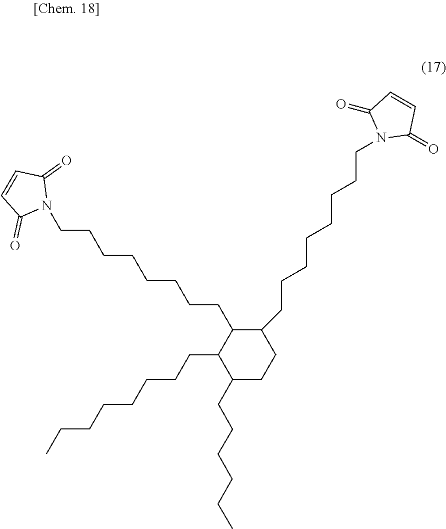 [SMILES: CCCCCCCCC1C(CCCCCC)CCC(CCCCCCCCN2C(=O)C=CC2=O)C1CCCCCCCCN1C(=O)C=CC1=O]

Examples of maleimide compounds represented by Formula (12) include BMI-1500 (product name, in Formula (12), n₇=1.3, functional group equivalent: 754 g/eq., commercially available from Designer Molecules Inc.).

As the maleimide compounds represented by Formula (13), commercial products can be used, and examples thereof include BMI-1700 (product name, commercially available from Designer Molecules Inc. (DMI)).

As the maleimide compounds represented by Formula (14), commercial products can be used, and examples thereof include BMI-3000 (product name, commercially available from Designer Molecules Inc. (DMI)), BMI-5000 (product name, commercially available from Designer Molecules Inc. (DMI)), and BMI-9000 (product name, commercially available from Designer Molecules Inc. (DMI)).

As the maleimide compounds represented by Formula (15), commercial products can be used, and examples thereof include BMI-TMH (product name, commercially available from Daiwa Fine Chemicals Co., Ltd.).

As the maleimide compounds represented by Formula (16), commercial products can be used, and examples thereof include BMI-70 (product name, commercially available from K⋅I Chemical Industry Co., Ltd.).

These maleimide compounds (B1) can be used alone or two or more thereof can be appropriately used in combination.

In the resin composition, the content of the maleimide compound (B1) with respect to a total of 100 parts by mass of the bismaleimide compound (A), the maleimide compound (B-1) and the photocuring initiator (C) is preferably 0.5 to 85 parts by mass.

### Cyanic Acid Ester Compound

In the resin composition, a cyanic acid ester compound (B-2) (also referred to as a component (B-2)) can be used. Hereinafter, the cyanic acid ester compound (B-2) will be described.

The cyanic acid ester compound is not particularly limited as long as it is a resin having an aromatic moiety in which at least one cyanato group (cyanic acid ester group) is substituted in the molecule.

For example, those represented by the following Formula (18) may be exemplified.

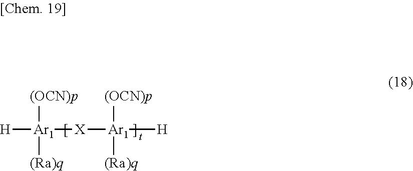

In Formula (18), Ar₁ indicates a benzene ring, a naphthalene ring or a single bond of two benzene rings. If there are a plurality of Ar₁′, they may be the same as or different from each other. Ar₁ is preferably a naphthalene ring. Ra's each independently indicate a hydrogen atom, a C1-C6 alkyl group, a C2-C6 alkenyl group, a C6-C12 aryl group, a C1-C4 alkoxy group, or a group in which a C1-C6 alkyl group and a C6-C12 aryl group are bonded. Ra is preferably a hydrogen atom. The aromatic ring for Ra may have a substituent, and substituents for Ar₁ and Ra can be selected at arbitrary positions. p indicates the number of cyanato groups bonded to Ar₁, and each independently indicate an integer of 1 to 3 and is preferably 1. q indicates the number of Ra atoms boned to Ar1, and is 4-p when Ar₁ is a benzene ring, 6-p when Ar₁ is a naphthalene ring, and 8-p when two benzene rings are single-bonded. t indicates an average number of repetitions, an integer of 0 to 50, and is preferably an integer of 1 to 30, and more preferably an integer of 1 to 10. The cyanic acid ester compound may be a mixture of compounds with different t. When there are a plurality of X's, they each independently indicate a single bond, a C1-050 divalent organic group (a hydrogen atom may be substituted with a hetero atom), a divalent organic group having 1 to 10 nitrogen atoms (for example, —N—R—N— (here, R indicates an organic group)), a carbonyl group (—CO—), a carboxy group (—C(═O)O—), a carbonyl dioxide group (—OC(═O)O—), a sulphonyl group (—SO₂—), a divalent sulfur atom or a divalent oxygen atom.

The alkyl group for Ra in Formula (18) may have either a linear or branched chain structure or a cyclic structure (for example, a cycloalkyl group, etc.).

In addition, a hydrogen atom in the alkyl group in Formula (18) and the aryl group for Ra may be substituted with a halogen atom such as a fluorine atom and a chlorine atom, an alkoxy group such as a methoxy group and a phenoxy group, a cyano group or the like.

Specific examples of alkyl groups include a methyl group, ethyl group, propyl group, isopropyl group, n-butyl group, isobutyl group, tert-butyl group, n-pentyl group, 1-ethyl propyl group, 2,2-dimethylpropyl group, cyclopentyl group, hexyl group, cyclohexyl group, and trifluoromethyl group.

Specific examples of alkenyl groups include a vinyl group, (meth)allyl group, isopropenyl group, 1-propenyl group, 2-butenyl group, 3-butenyl group, 1,3-butandienyl group, 2-methyl-2-propenyl, 2-pentenyl group, and 2-hexenyl group.

Specific examples of aryl groups include a phenyl group, xylyl group, mesityl group, naphthyl group, phenoxy phenyl group, ethyl phenyl group, o-, m- or p-fluoro phenyl group, dichloro phenyl group, dicyano phenyl group, trifluoro phenyl group, methoxy phenyl group, and o-, m- or p-tolyl group. In addition, examples of alkoxy groups include a methoxy group, ethoxy group, propoxy group, isopropoxy group, n-butoxy group, isobutoxy group, and tert-butoxy group.

Specific examples of C1-C50 divalent organic groups for X in Formula (18) include a methylene group, ethylene group, trimethylene group, cyclopentylene group, cyclohexylene group, trimethylcyclohexylene group, biphenylyl-methylene group, dimethylmethylene-phenylene-dimethylmethylene group, methylene-phenylene-methylene group, fluorenediyl group, and phthalidodiyl group. Among these, a methylene-phenylene-methylene group is preferable. A hydrogen atom in the divalent organic group may be substituted with a halogen atom such as a fluorine atom and a chlorine atom, an alkoxy group such as a methoxy group and a phenoxy group, a cyano group or the like.

Examples of divalent organic groups having 1 to 10 nitrogen atoms for X in Formula (18) include imino groups and polyimide groups.

In addition, examples of organic groups for X in Formula (18) include those having a structure represented by the following Formula (19) or the following Formula (20).

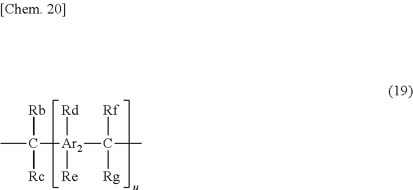

In Formula (19), Ar₂ indicates a benzenediyl group, a naphthalenediyl group or a biphenyldiyl group, and if u is an integer of 2 or more, they may be the same as or different from each other. Rb, Rc, Rf, and Rg each independently indicate a hydrogen atom, a C1-C6 alkyl group, a C6-C12 aryl group, a trifluoromethyl group, or an aryl group having at least one phenolic hydroxy group. Rd and Re are each independently selected from among a hydrogen atom, a C1-C6 alkyl group, a C6-C12 aryl group, a C1-C4 alkoxy group, and a hydroxy group. u indicates an integer of 0 to 5.

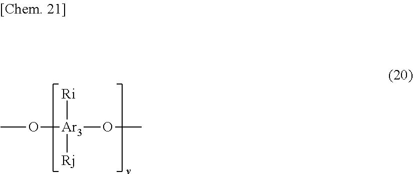

In Formula (20), Ar₃ indicates a benzenediyl group, a naphthalenediyl group or a biphenyldiyl group, and if v is an integer of 2 or more, they may be the same as or different from each other. Ri and Rj each independently indicate a hydrogen atom, a C1-C6 alkyl group, a C6-C12 aryl group, benzyl group, a C1-C4 alkoxy group, a hydroxy group, a trifluoromethyl group, or an aryl group in which at least one cyanato group is substituted. v indicates an integer of 0 to 5, and a mixture of compounds with different v may be used.

In addition, as X in Formula (18), divalent groups represented by the following formula may be exemplified.

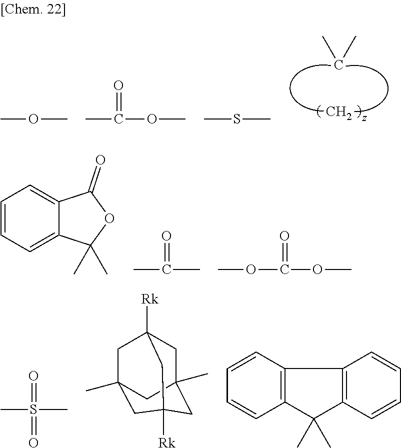

Here, in the above formula, z indicates an integer of 4 to 7. Rk's each independently indicate a hydrogen atom or a C1-C6 alkyl group.

Specific examples of Ar₂ in Formula (19) and Ar₃ in Formula (20) include benzenediyl groups in which two carbon atoms represented by Formula (19) or two oxygen atoms represented by Formula (20) are bonded to the 1,4 positions or 1,3 positions, biphenyl diyl groups in which two carbon atoms or two oxygen atoms are bonded to the 4,4′ positions, 2,4′ positions, 2,2′ positions, 2,3′ positions, 3,3′ positions, or 3,4′ positions, and naphthalenediyl groups in which two carbon atoms or two oxygen atoms are bonded to the 2,6 positions, 1,5 positions, 1,6 positions, 1,8 positions, 1,3 positions, 1,4 positions, or 2,7 positions.

The alkyl groups and aryl groups for Rb, Rc, Rd, Re, Rf and Rg in Formula (19) and Ri and Rj in Formula (20) have the same meanings as in Formula (18).

Specific examples of cyanato-substituted aromatic compounds represented by Formula (18) include cyanatobenzene, 1-cyanato-2-, 1-cyanato-3-, or 1-cyanato-4-methylbenzene, 1-cyanato-2-, 1-cyanato-3-, or 1-cyanato-4-methoxybenzene, 1-cyanato-2,3-, 1-cyanato-2,4-, 1-cyanato-2,5-, 1-cyanato-2,6-, 1-cyanato-3,4- or 1-cyanato-3,5-dimethylbenzene, cyanatoethylbenzene, cyanatobutylbenzene, cyanatooctylbenzene, cyanatononylbenzene, 2-(4-cyanaphenyl)-2-phenylpropane (4-α-cumylphenol cyanate), 1-cyanato-4-cyclohexylbenzene, 1-cyanato-4-vinylbenzene, 1-cyanato-2- or 1-cyanato-3-chlorobenzene, 1-cyanato-2,6-dichlorobenzene, 1-cyanato-2-methyl-3-chlorobenzene, cyanatonitrobenzene, 1-cyanato-4-nitro-2-ethylbenzene, 1-cyanato-2-methoxy-4-allylbenzene (eugenol cyanate), methyl(4-cyanatophenyl)sulfide, 1-cyanato-3-trifluoromethylbenzene, 4-cyanatobiphenyl, 1-cyanato-2- or 1-cyanato-4-acetylbenzene, 4-cyanatobenzaldehyde, 4-cyanatobenzoic acid methyl ester, 4-cyanatobenzoic acid phenyl ester, 1-cyanato-4-acetaminobenzene, 4-cyanatobenzophenone, 1-cyanato-2,6-di-tert-butylbenzene, 1,2-dicyanatobenzene, 1,3-dicyanatobenzene, 1,4-dicyanatobenzene, 1,4-dicyanato-2-tert-butylbenzene, 1,4-dicyanato-2,4-dimethylbenzene, 1,4-dicyanato-2,3,4-dimethylbenzene, 1,3-dicyanato-2,4,6-trimethylbenzene, 1,3-dicyanato-5-methylbenzene, 1-cyanato or 2-cyanatonaphthalene, 1-cyanato-4-methoxynaphthalene, 2-cyanato-6-methoxynaphthalene, 2-cyanato-7-methoxynaphthalene, 2,2′-dicyanato-1,1′-binaphthyl, 1,3-, 1,4-, 1,5-, 1,6-, 1,7-, 2,3-, 2,6- or 2,7-dicyanatonaphthalene, 2,2′- or 4,4′-dicyanatobiphenyl, 4,4′-dicyanatooctafluorobiphenyl, 2,4′- or 4,4′-dicyanatodiphenylmethane, bis(4-cyanato-3,5-dimethylphenyl)methane, 1,1-bis(4-cyanatophenyl)ethane, 1,1-bis(4-cyanatophenyl)propane, 2,2-bis(4-cyanatophenyl)propane, 2,2-bis(4-cyanato-3-methylphenyl)propane, 2,2-bis(2-cyanato-5-biphenylyl)propane, 2,2-bis(4-cyanatophenyl)hexafluoropropane, 2,2-bis(4-cyanato-3,5-dimethylphenyl)propane, 1,1-bis(4-cyanatophenyl)butane, 1,1-bis(4-cyanatophenyl)isobutane, 1,1-bis(4-cyanatophenyl)pentane, 1,1-bis(4-cyanatophenyl)-3-methylbutane, 1,1-bis(4-cyanatophenyl)-2-methylbutane, 1,1-bis(4-cyanatophenyl)-2,2-dimethylpropane, 2,2-bis(4-cyanatophenyl)butane, 2,2-bis(4-cyanatophenyl)pentane, 2,2-bis(4-cyanatophenyl)hexane, 2,2-bis(4-cyanatophenyl)-3-methylbutane, 2,2-bis(4-cyanatophenyl)-4-methylpentane, 2,2-bis(4-cyanatophenyl)-3,3-dimethylbutane, 3,3-bis(4-cyanatophenyl)hexane, 3,3-bis(4-cyanatophenyl)heptane, 3,3-bis(4-cyanatophenyl)octane, 3,3-bis(4-cyanatophenyl)-2-methylpentane, 3,3-bis(4-cyanatophenyl)-2-methylhexane, 3,3-bis(4-cyanatophenyl)-2,2-dimethylpentane, 4,4-bis(4-cyanatophenyl)-3-methylheptane, 3,3-bis(4-cyanatophenyl)-2-methylheptane, 3,3-bis(4-cyanatophenyl)-2,2-dimethylhexane, 3,3-bis(4-cyanatophenyl)-2,4-dimethylhexane, 3,3-bis(4-cyanatophenyl)-2,2,4-trimethylpentane, 2,2-bis(4-cyanatophenyl)-1,1,1,3,3,3-hexafluoro propane, bis(4-cyanatophenyl)phenylmethane, 1,1-bis(4-cyanatophenyl)-1-phenylethane, bis(4-cyanatophenyl)biphenylmethane, 1,1-bis(4-cyanatophenyl)cyclopentane, 1,1-bis(4-cyanatophenyl)cyclohexane, 2,2-bis(4-cyanato-3-isopropylphenyl)propane, 1,1-bis(3-cyclohexyl-4-cyanatophenyl)cyclohexane, bis(4-cyanatophenyl)diphenylmethane, bis(4-cyanatophenyl)-2,2-dichloroethylene, 1,3-bis[2-(4-cyanatophenyl)-2-propyl]benzene, 1,4-bis[2-(4-cyanatophenyl)-2-propyl]benzene, 1,1-bis(4-cyanatophenyl)-3,3,5-trimethylcyclohexane, 4[bis(4-cyanatophenyl)methyl]biphenyl, 4,4-dicyanatobenzophenone, 1,3-bis(4-cyanatophenyl)-2-propen-1-one, bis(4-cyanatophenyl)ether, bis(4-cyanatophenyl) sulfide, bis(4-cyanatophenyl)sulfone, 4-cyanatobenzoic acid-4-cyanatophenyl ester(4-cyanatophenyl-4-cyanatobenzoate), bis-(4-cyanatophenyl)carbonate, 1,3-bis(4-cyanatophenyl)adamantane, 1,3-bis(4-cyanatophenyl)-5,7-dimethyladamantane, 3,3-bis(4-cyanatophenyl)isobenzofuran-1(3H)-one (phenolphthalein cyanate), 3,3-bis(4-cyanato-3-methylphenyl)isobenzofuran-1(3H)-one(o-cresolphthalein cyanate), 9,9′-bis(4-cyanatophenyl)fluorene, 9,9-bis(4-cyanato-3-methylphenyl)fluorene, 9,9-bis(2-cyanato-5-biphenylyl)fluorene, tris(4-cyanatophenyl)methane, 1,1,1-tris(4-cyanatophenyl)ethane, 1,1,3-tris(4-cyanatophenyl)propane, α,α,α′-tris(4-cyanatophenyl)-1-ethyl-4-isopropylbenzene, 1,1,2,2-tetrakis(4-cyanatophenyl)ethane, tetrakis(4-cyanatophenyl)methane, 2,4,6-tris(N-methyl-4-cyanatoanilino)-1,3,5-triazine, 2,4-bis(N-methyl-4-cyanatoanilino)-6-(N-methylanilino)-1,3,5-triazine, bis(N-4-cyanato-2-methylphenyl)-4,4′-oxydiphthalimide, bis(N-3-cyanato-4-methylphenyl)-4,4′-oxydiphthalimide, bis(N-4-cyanatophenyl)-4,4′-oxydiphthalimide, bis(N-4-cyanato-2-methylphenyl)-4,4′-(hexafluoroisopropylidene)diphthalimide, tris(3,5-dimethyl-4-cyanatobenzyl)isocyanurate, 2-phenyl-3,3-bis(4-cyanatophenyl)phthalimidine, 2-(4-methylphenyl)-3,3-bis(4-cyanatophenyl)phthalimidine, 2-phenyl-3,3-bis(4-cyanato-3-methylphenyl)phthalimidine, 1-methyl-3,3-bis(4-cyanatophenyl)indolin-2-one, 2-phenyl-3,3-bis(4-cyanatophenyl)indolin-2-one, and α-naphthol aralkyl type cyanic acid ester resins. Among these, α-naphthol aralkyl type cyanic acid ester resins (including those in which n₁₈ is 1 to 4 in Formula (28) to be described below) represented by the following Formula (28) are preferable because the heat resistance of the cured object is improved.

These cyanic acid ester compounds can be used alone or two or more thereof can be appropriately used in combination.

Other specific examples of cyanic acid ester compounds represented by Formula (18) include phenolic resins such as phenol novolac resins and cresol novolac resins (those obtained by reacting phenol, alkyl-substituted phenol or halogen-substituted phenol with a formaldehyde compound such as formalin or paraformaldehyde in an acidic solution by a known method), trisphenol novolac resin (those obtained by reacting hydroxybenzaldehyde and phenol in the presence of an acidic catalyst), fluorene novolac resin (those obtained by reacting a fluorenone compound and 9,9-bis(hydroxyaryl)fluorenes in the presence of an acidic catalyst), phenol aralkyl resins, cresol aralkyl resins, naphthol aralkyl resins and biphenyl aralkyl resins (those obtained by reacting a bishalogenomethyl compound represented by Ar₄-(CH₂Y)₂ (Ar₄ indicates a phenyl group, Y indicates a halogen atom, hereinafter the same applies in this paragraph) and a phenol compound in the presence of an acidic catalyst or without a catalyst, those obtained by reacting a bis(alkoxymethyl) compound represented by Ar₄-(CH₂OR)₂ (R indicates an alkyl group) and a phenol compound in the presence of an acidic catalyst, or those obtained by reacting a bis(hydroxy methyl) compound represented by Ar₄-(CH₂OH)₂ and a phenol compound in the presence of an acidic catalyst, or those obtained by polycondensation of an aromatic aldehyde compound, an aralkyl compound and a phenol compound by a known method), phenol-modified xylene formaldehyde resins (those obtained by reacting a xylene formaldehyde resin and a phenol compound in the presence of an acidic catalyst by a known method), modified naphthalene formaldehyde resins (those obtained by reacting a naphthalene formaldehyde resin and a hydroxy-substituted aromatic compound in the presence of an acidic catalyst by a known method), and phenol-modified dicyclopentadiene resins, and phenolic resins having a polynaphthylene ether structure (those obtained by dehydration condensation of a polyvalent hydroxy naphthalene compound having two or more phenolic hydroxy groups in one molecule in the presence of a basic catalyst by a known method), and those cyanated by the same method as above, and prepolymers thereof. These cyanic acid ester compounds can be used alone or two or more thereof can be appropriately used in combination.

A method of producing such a cyanic acid ester compound is not particularly limited, and known methods can be used. Examples of such production methods include methods in which a hydroxy group-containing compound having a desired framework is obtained and synthesized and hydroxy groups are modified by a known technique to be converted into a cyanate. Examples of techniques for converting hydroxy groups into a cyanate include techniques described in Ian Hamerton, Chemistry and Technology of Cyanate Ester Resins, Blackie Academic & Professional.

Cured objects using these cyanic acid ester compounds have excellent properties such as a glass transition temperature, low thermal expansion, and plating adhesion.

In the resin composition, the content of the cyanic acid ester compound is preferably 0.5 to 85 parts by mass with respect to a total of 100 parts by mass of the bismaleimide compound (A), the cyanic acid ester compound (B-2) and the photocuring initiator (C).

### Benzoxazine Compound

In the resin composition, a benzoxazine compound (B-3) (also referred to as a component (B-3)) can be used. Hereinafter, the benzoxazine compound (B-3) will be described.

As the benzoxazine compound (B-3), a generally known compound can be used as long as it has an oxazine ring as a basic framework. The benzoxazine compound also includes a compound having a polycyclic oxazine framework such as a naphthoxazine compound.

As the benzoxazine compound (B-3), compounds represented by Formula (21) and compounds represented by Formula (22) are preferable because favorable photocurability is obtained.

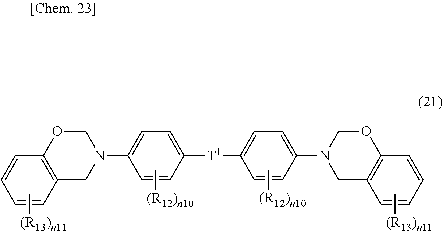

In Formula (21), R₁₂'s each independently indicate a hydrogen atom, an aryl group, an aralkyl group, an alkenyl group, an alkyl group, or a cycloalkyl group. n₁₀'s each independently indicate an integer of 1 to 4. R₁₃'s each independently indicate a hydrogen atom, an aryl group, an aralkyl group, an alkenyl group, an alkyl group, or a cycloalkyl group. n₁₁'s each independently indicate an integer of 1 to 4. T¹ indicates an alkylene group, a group represented by Formula (22), a group represented by the formula “—SO₂—”, a group represented by “—CO—”, an oxygen atom, or a single bond.

The aryl group for both R₁₂ and R₁₃ is preferably a C6-C18 aryl group. Examples of aryl groups include a phenyl group, naphthyl group, indenyl group, biphenyl group, and antolyl group. Among these, a phenyl group is more preferable. These aryl groups may have one or more, and preferably 1 to 3 C1-C4 lower alkyl groups. Examples of aryl groups having such lower alkyl groups include a tolyl group, xylyl group, and methylnaphthyl group.

The aralkyl groups for both R₁₂ and R₁₃ are preferably benzyl groups and phenethyl groups. These may have 1 or more, and preferably, 1 to 3 C1-C4 lower alkyl groups on the phenyl group.

Examples of alkenyl groups for both R₁₂ and R₁₃ include a vinyl group, (meth)allyl group, propenyl group, butenyl group, and hexenyl group. Among these, a vinyl group, allyl group, and propenyl group are preferable, and an allyl group is more preferable.

The alkyl group for both R₁₂ and R₁₃ is preferably a C1-C20 alkyl group and more preferably a C1-C10 alkyl group. Alkyl groups having 3 or more carbon atoms may be linear or branched. Examples thereof include a methyl group, ethyl group, n-propyl group, isopropyl group, n-butyl group, isobutyl group, sec-butyl group, t-butyl group, n-pentyl group, neopentyl group, n-hexyl group, thexyl group, n-heptyl group, n-octyl group, n-ethylhexyl group, n-nonyl group, and n-decyl group.

Examples of cycloalkyl groups for both R₁₂ and R₁₃ include a cyclopentyl group, cyclohexyl group, and a cycloheptyl group. A cyclohexyl group is preferable.

The alkylene group for T¹ is preferably a linear or branched alkylene group. Examples of linear alkylene groups include a methylene group, ethylene group, propylene group, butylene group, pentylene group, hexylene group, heptylene group, octylene group, nonylene group, decanylene group, trimethylene group, tetramethylene group, pentamethylene group, and hexamethylene group. Examples of branched alkylene groups include alkylmethylene groups of —C(CH₃)₂—, —CH(CH₃)—, —CH(CH₂CH₃)—, —C(CH₃)(CH₂CH₃)—, —C(CH₃)(CH₂CH₂CH₃)—, and —C(CH₂CH₃)₂—; and alkylethylene groups of —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—.

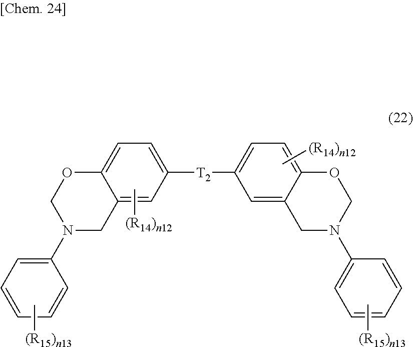

In Formula (22), R₁₄'s each independently indicate a hydrogen atom, an aryl group, an aralkyl group, an alkenyl group, an alkyl group, or a cycloalkyl group. n₁₂'s each independently indicate an integer of 1 to 3. R₁₅'s each independently indicate a hydrogen atom, an aryl group, an aralkyl group, an alkenyl group, an alkyl group, or a cycloalkyl group. n₁₃'s each independently indicate an integer of 1 to 5. T₂ indicates an alkylene group, a group represented by Formula (22), a group represented by the formula “—SO₂—”, a group represented by “—CO—”, an oxygen atom, or a single bond.

The aryl groups, aralkyl groups, alkenyl groups, alkyl groups, and cycloalkyl groups for both R₁₄ and R₁₅ are as described above. The alkylene group for T₂ is as described above.

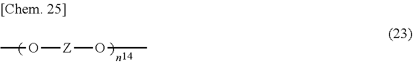

In Formula (23), Z is an alkylene group or a hydrocarbon group having an aromatic ring and 6 or more and 30 or less carbon atoms. n₁₄ indicates an integer of 0 or more and 5 or less. n₁₄ is preferably an integer of 1 or more and 3 or less and more preferably 1 or 2.

The alkylene group for Z is as described above.

Examples of hydrocarbon groups having an aromatic ring and 6 or more and 30 or less carbon atoms include divalent groups obtained by removing two hydrogen atoms from nuclei of aromatic compounds such as benzene, biphenyl, naphthalene, anthracene, fluorene, phenanthrene, indacene, terphenyl, acenaphthylene, and phenalene.

As the benzoxazine compound (B-3), commercial products may be used, and examples thereof include P-d type benzoxazine (commercially available from Shikoku Chemical Corporation, 3,3′-(methylene-1,4-diphenylene)bis(3,4-dihydro-2H-1,3-benzoxazine), compounds represented by Formula (20)), F-a type benzoxazine (commercially available from Shikoku Chemical Corporation, 2,2-bis(3,4-dihydro-2H-3-phenyl-1,3-benzoxazinyl)methane, compounds represented by Formula (21)), bisphenol A type benzoxazine BA-BXZ (product name, commercially available from Konishi Chemical Industry Co., Ltd.), bisphenol F type benzoxazine BF-BXZ (product name, commercially available from Konishi Chemical Industry Co., Ltd.), bisphenol S type benzoxazine BS-BXZ (product name, commercially available from Konishi Chemical Industry Co., Ltd.), and phenolphthalein type benzoxazine.

These benzoxazine compounds (B-3) can be used alone or two or more thereof can be appropriately used in combination.

As the benzoxazine compound, compounds represented by Formula (20) and compounds represented by Formula (21) are preferable, and 3,3′-(methylene-1,4-diphenylene)bis(3,4-dihydro-2H-1,3-benzoxazine) is more preferable because they have favorable heat resistance.

In the resin composition, the content of the benzoxazine compound is preferably 0.5 to 85 parts by mass with respect to a total of 100 parts by mass of the bismaleimide compound (A), the benzoxazine compound (B-3) and the photocuring initiator (C).

### Epoxy Resin

In the resin composition, an epoxy resin (B-4) (also referred to as a component (B-4)) can be used. Hereinafter, the epoxy resin (B-4) will be described.

As the epoxy resin (B-4), generally known resins can be used. Examples thereof include a bisphenol A type epoxy resin, bisphenol E type epoxy resin, bisphenol F type epoxy resin, bisphenol S type epoxy resin, bisphenol A novolac type epoxy resin, biphenyl type epoxy resin, phenol novolac type epoxy resin, cresol novolac type epoxy resin, xylene novolac type epoxy resin, multifunctional phenol type epoxy resin, naphthalene type epoxy resin, naphthalene framework-modified novolac type epoxy resin, naphthylene ether type epoxy resin, phenolaralkyl type epoxy resin, anthracene type epoxy resin, trifunctional phenol type epoxy resin, tetrafunctional phenol type epoxy resin, triglycidyl isocyanurate, glycidyl ester type epoxy resin, alicyclic epoxy resin, dicyclopentadiene novolac type epoxy resin, biphenyl novolac type epoxy resin, phenolaralkyl novolac type epoxy resin, naphthol aralkyl novolac type epoxy resin, aralkyl novolac type epoxy resin, naphthol aralkyl type epoxy resin, dicyclopentadiene type epoxy resin, polyol type epoxy resin, phosphorus-containing epoxy resin, glycidyl amine, compounds with epoxidized double bonds such as butadiene, compounds obtained by reacting hydroxyl group-containing silicone resins with epichlorohydrin and halides thereof. These epoxy resins can be used alone or two or more thereof can be appropriately used in combination.

As the epoxy resin, commercial products can be used. Examples of commercial products include epoxy resins represented by the following Formula (24) (NC-3000FH (product name, commercially available from Nippon Kayaku Co., Ltd.), in the following Formula (24), n₁₅ is 3 to 5, about 4), and naphthalene type epoxy resins represented by the following Formula (25) (HP-4710 (product name, commercially available from DIC)).

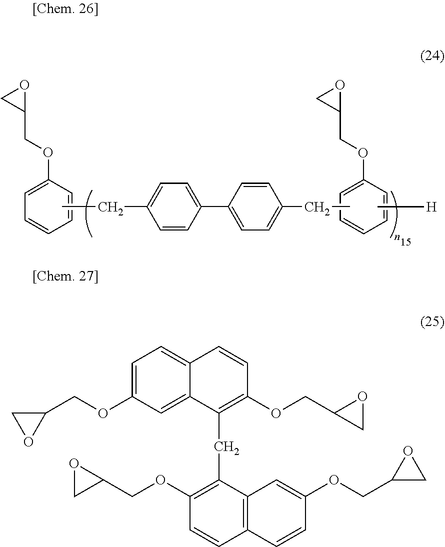

These epoxy resins can be used alone or two or more thereof can be appropriately used in combination.

As the epoxy resin, the epoxy resins represented by Formula (23) and the epoxy resins represented by Formula (24) are preferable, and the epoxy resins represented by Formula (23) are more preferable because the cured object has excellent heat resistance.

In the resin composition, the content of the epoxy resin with respect to a total of 100 parts by mass of the bismaleimide compound (A), the epoxy resin (B4) and the photocuring initiator (C) is preferably 0.5 to 85 parts by mass.

### Carbodiimide Compound

In the resin composition, a carbodiimide compound (B-5) (also referred to as a component (B-5)) can be used. Hereinafter, the carbodiimide compound (B-5) will be described.

As the carbodiimide compound (B-5), generally known compounds can be used as long as they have one or more carbodiimide groups in at least molecule. Examples thereof include polycarbodiimides such as N,N′-dicyclohexylcarbodiimide, dicyclohexylcarbodiimide, diisopropylcarbodiimide, dimethylcarbodiimide, diisobutylcarbodiimide, dioctylcarbodiimide, t-butyl isopropyl carbodiimide, diphenyl carbodiimide, di-t-butyl carbodiimide, di-β-naphthylcarbodiimide, N,N′-di-2,6-diisopropylphenylcarbodiimide, 2,6,2′,6′-tetraisopropyldiphenylcarbodiimide, cyclic carbodiimide, Carbodilite (registered trademark) B-01 (commercially available from Nisshinbo Chemical Inc.), and Stabaxol (registered trademark: commercially available from Rhein Chemie).

These carbodiimide compounds (B-5) can be used alone or two or more thereof can be appropriately used in combination.

The carbodiimide compound has favorable heat resistance and favorable adhesion to the conductor layer when used in the insulating layer of the printed wiring board, and thus Carbodilite (registered trademark) B-01, V-03, and V05 (all names of products, commercially available from Nisshinbo Chemical Inc.) is preferable, and Carbodilite (registered trademark) B-01 (product name, commercially available from Nisshinbo Chemical Inc.) is more preferable.

In the resin composition, the content of the carbodiimide compound with respect to 100 parts by mass of the resin solid component in the resin composition is preferably 0.5 to 85 parts by mass.

### Compound Having Ethylenically Unsaturated Group

In the resin composition, a compound (B-6) having an ethylenically unsaturated group (also referred to as a component (B-6)) can be used. Hereinafter, the compound (B-6) having an ethylenically unsaturated group will be described.

As the compound (B-6) having an ethylenically unsaturated group, generally known compounds can be used as long as they are compounds having one or more ethylenically unsaturated groups in one molecule. Examples thereof include compounds having a (meth)acryloyl group, a vinyl group and the like.

Examples of compounds having a (meth)acryloyl group include methyl(meth)acrylate, ethyl(meth)acrylate, butyl(meth)acrylate, lauryl(meth)acrylate, polyethylene glycol(meth)acrylate, polyethylene glycol(meth)acrylate monomethyl ether, phenylethyl(meth)acrylate, isobornyl(meth)acrylate, cyclohexyl(meth)acrylate, benzyl(meth)acrylate, tetrahydrofurfuryl(meth)acrylate, butanediol di(meth)acrylate, hexanediol di(meth)acrylate, neopentyl glycol di(meth)acrylate, nonanediol di(meth)acrylate, glycol di(meth)acrylate, diethylene di(meth)acrylate, polyethylene glycol di(meth)acrylate, tris(meth)acryloyloxyethyl isocyanurate, polypropylene glycol di(meth)acrylate, adipate epoxy di(meth)acrylate, bisphenol ethylene oxide di(meth)acrylate, hydrogenated bisphenol ethylene oxide (meth)acrylate, bisphenol di(meth)acrylate, ε-caprolactone-modified hydroxy pivalic acid neopentine glycol di(meth)acrylate, ε-caprolactone-modified dipentaerythritol hexa(meth)acrylate, ε-caprolactone-modified dipentaerythritol poly(meth)acrylate, dipentaerythritol poly(meth)acrylate, trimethylolpropane tri(meth)acrylate, triethylolpropane tri(meth)acrylate, and ethylene oxide adducts thereof; pentaerythritol tri(meth)acrylate, and ethylene oxide adducts thereof; pentaerythritol tetra(meth)acrylate, dipentaerythritol hexa(meth)acrylate, and ethylene oxide adducts thereof.

In addition to these, urethane (meth)acrylates having both a (meth)acryloyl group and a urethane bond in the same molecule; polyester (meth)acrylates having both a (meth)acryloyl group and an ester bond in the same molecule; epoxy (meth)acrylates derived from an epoxy resin and having a (meth)acryloyl group; and reactive oligomers in which these bonds are combined may be exemplified.

Examples of urethane (meth)acrylates include reaction products of a hydroxyl group-containing (meth)acrylate, a polyisocyanate, and other alcohols used as necessary. Examples thereof include hydroxyalkyl(meth)acrylates such as hydroxyethyl(meth)acrylate, hydroxypropyl(meth)acrylate, and hydroxybutyl(meth)acrylate; glycerin (meth)acrylates such as glycerin mono(meth)acrylate and glycerin di(meth)acrylate; and urethane (meth)acrylates obtained by reacting sugar alcohol (meth)acrylates such as pentaerythritol di(meth)acrylate, pentaerythritol tri(meth)acrylate, dipentaerythritol penta(meth)acrylate, and dipentaerythritol hexa(meth)acrylate with polyisocyanates such as toluene diisocyanate, hexamethylene diisocyanate, trimethylhexamethylene diisocyanate, isophorone diisocyanate, norbornene diisocyanate, xylene diisocyanate, hydrogenated xylene diisocyanate, dicyclohexanemethylene diisocyanate, and isocyanurates thereof, and burette reaction products.

Examples of polyester (meth)acrylates include monofunctional (poly)ester(meth)acrylates such as caprolactone-modified 2-hydroxyethyl(meth)acrylate, ethylene oxide and/or propylene oxide-modified phthalic acid (meth)acrylate, ethylene oxide-modified succinic acid (meth)acrylate, and caprolactone-modified tetrahydrofurfuryl(meth)acrylate; di(poly)ester (meth)acrylates such as hydroxypivalic acid ester neopentyl glycol di(meth)acrylate, caprolactone-modified hydroxypivalic acid ester neopentyl glycol di(meth)acrylate, and epichlorohydrin-modified phthalate di(meth)acrylate; and triol mono-, di- or tri(meth)acrylates obtained by adding 1 mol or more of a cyclic lactone compound such as ε-caprolactone, γ-butyrolactone, and δ-valerolactone to 1 mol of trimethylolpropane or glycerin.

Triol mono-, di-, tri- or tetra(meth)acrylates obtained by adding 1 mol or more of a cyclic lactone compound such as ε-caprolactone, γ-butyrolactone, and δ-valerolactone to 1 mol of pentaerythritol; mono(meth)acrylates or poly(meth)acrylates of polyhydric alcohol such as triol mono or poly(meth)acrylate triol, tetraol, pentaol or hexaol obtained by adding 1 mol or more of a cyclic lactone compound such as ε-caprolactone, γ-butyrolactone, and δ-valerolactone to 1 mol of dipentaerythritol may be exemplified.

In addition, examples thereof include (meth)acrylates of polyester polyols which are reaction products of diol components such as (poly)ethylene glycol, (poly)propylene glycol, (poly)tetramethylene glycol, (poly)butylene glycol, 3-methyl-1,5-pentanediol, and hexanediol and polyacids such as maleic acid, fumaric acid, succinic acid, adipic acid, phthalic acid, isophthalic acid, hexahydrophthalic acid, tetrahydrophthalic acid, dimer acid, sebacic acid, azelaic acid, and 5-sulfoisophthalic acid sodium and anhydrides thereof; and polyfunctional (poly)ester (meth)acrylates such as (meth)acrylates of cyclic lactone-modified polyester diols including the diol components, polyacids and anhydrides thereof, ε-caprolactone, γ-butyrolactone, δ-valerolactone and the like.

Epoxy (meth)acrylates are carboxylate compounds of a compound having an epoxy group and (meth)acrylic acid. Examples thereof include phenol novolac type epoxy (meth)acrylate, cresol novolac type epoxy (meth)acrylate, trishydroxyphenylmethane type epoxy (meth)acrylate, dicyclopentadiene phenol type epoxy (meth)acrylate, bisphenol A type epoxy (meth)acrylate, bisphenol F type epoxy (meth)acrylate, biphenol type epoxy (meth)acrylate, bisphenol A novolac type epoxy (meth)acrylate, naphthalene framework-containing epoxy (meth)acrylate, glyoxal type epoxy (meth)acrylate, heterocyclicepoxy (meth)acrylate, and acid anhydride-modified epoxy acrylates thereof.

Examples of compounds having a vinyl group include vinyl ethers such as ethyl vinyl ether, propyl vinyl ether, hydroxyethyl vinyl ether, and ethylene glycol divinyl ether; and styrenes such as styrene, methylstyrene, ethylstyrene, and divinylbenzene. Examples of other vinyl compounds include triallyl isocyanurate, trimethallyl isocyanurate, and bisallylnadimide.

As compounds having an ethylenically unsaturated group, commercial products can be used, and examples thereof include dicyclopentadiene phenol type epoxy acrylates (KAYARAD (registered trademark) ZXA-101H (product name) commercially available from Nippon Kayaku Co., Ltd.), as compounds represented by Formula (26), and acid-modified dicyclopentadiene phenol type epoxy acrylates (KAYARAD (registered trademark) ZXA-1807H (product name), KAYARAD (registered trademark) ZXR-1810H (product name), KAYARAD (registered trademark) ZXR-1816H (product name), and KAYARAD (registered trademark) ZXR-1889H (product name) commercially available from Nippon Kayaku Co., Ltd.) as compounds represented by the following Formula (27).

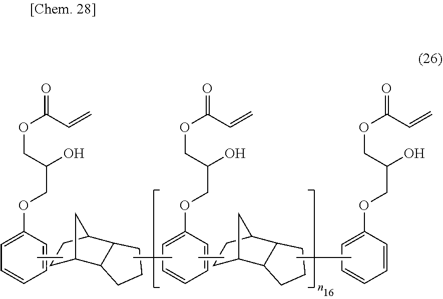

In Formula (26), n₁₆ indicates an integer of 0 to 10. n₁₆ is preferably an integer of 0 to 5 because a more suitable viscosity can be obtained and an increase in viscosity of the varnish can be better controlled.

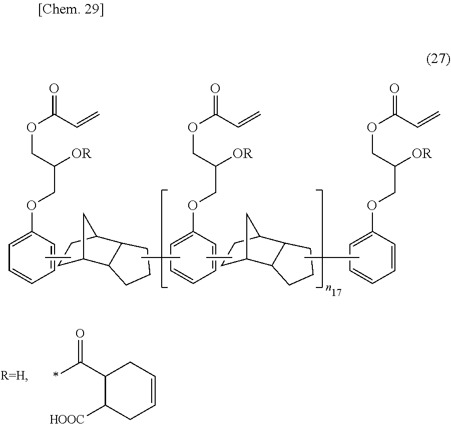

In Formula (27), n₁₇ indicates an integer of 0 to 10. n₁₇ is preferably an integer of 0 to 5 because a more suitable viscosity can be obtained and an increase in viscosity of the varnish can be better controlled.

These compounds having an ethylenically unsaturated group (B-6) can be used alone or two or more thereof can be appropriately used in combination.

The compound having an ethylenically unsaturated group is preferably a propylene glycol monomethyl ether acetate of a dicyclopentadiene phenol type epoxy acrylate compound because it has favorable thermal stability.

In the resin composition, the content of the compound having an ethylenically unsaturated group with respect to a total of 100 parts by mass of the bismaleimide compound (A), the benzoxazine compound (B-3) and the photocuring initiator (C) is preferably 0.5 to 85 parts by mass.

### Photocuring Initiator (C)

The resin composition according to the present embodiment contains the photocuring initiator (C) (also referred to as a component (C)). As the photocuring initiator (C), those known in the field that are generally used in the photocurable resin composition can be used. The photocuring initiator (C) is used together with the bismaleimide compound (A) and the resin or compound (B) for photocuring using various active energy rays.

Examples of photocuring initiators (C) include benzoins such as benzoin, benzoin methyl ether, benzoin ethyl ether, benzoin propyl ether, and benzoin isobutyl ether, organic peracids exemplified by benzoyl peroxide, lauroyl peroxide, acetyl peroxide, parachlorobenzoyl peroxide, di-tert-butyl-di-peroxyphthalate and the like; phosphine oxides such as 2,4,6-trimethylbenzoyl-diphenyl-phosphine oxide, and bis(2,4,6-trimethylbenzoyl)-phenylphosphine oxide; acetophenones such as acetophenone, 2,2-diethoxy-2-phenylacetophenone, 2,2-diethoxy-2-phenylacetophenone, 1,1-dichloroacetophenone, 2-hydroxy-2-methyl-phenylpropan-1-one, diethoxy acetophenone, 1-hydroxychlorohexylphenyl ketone, 2-methyl-1-[4-(methylthio)phenyl]-2-morpholino-propane-1-one, and 2-benzyl-2-dimethylamino-1-(4-morpholinophenyl)-butanone-1; anthraquinones such as 2-ethylanthraquinone, 2-t-butylanthraquinone, 2-chloroanthraquinone, and 2-amylanthraquinone; thioxanthones such as 2,4-diethylthioxanthone, 2-isopropylthioxanthone, and 2-chlorothioxanthone; ketals such as acetophenone dimethyl ketal, and benzyl dimethyl ketal; benzophenones such as benzophenone, 4-benzoyl-4′-methyl diphenyl sulfide, and 4,4′-bismethylaminobenzophenone; radical type photocuring initiators such as oxime esters, for example, 1,2-octanedione,1-[4-(phenylthio)-, 2-(O-benzoyloxime)], and 1-[9-ethyl-6-(2-methylbenzoyl)-9H-carbazol-3-yl]-ethanone-1-(O-acetyloxime), diazonium salts of Lewis acids such as p-methoxyphenyldiazonium fluorophosphonate, and N,N-diethylaminophenyldiazonium hexafluorophosphonate; iodonium salts of Lewis acids such as diphenyliodonium hexafluorophosphonate and diphenyliodonium hexafluoroantimonate; sulfonium salts of Lewis acids such as triphenylsulfonium hexafluorophosphonate, and triphenylsulfonium hexafluoroantimonate; phosphonium salts of Lewis acids such as triphenylphosphonium hexafluoroantimonate; other halides; triazine initiators; borate initiators; and cationic photocuring initiators such as other photoacid generators.

As the photocuring initiator (C), commercial products can also be used. Examples of commercial products include Omnirad (registered trademark) 369 (product name, commercially available from IGM Resins), Omnirad (registered trademark) 819 (product name, commercially available from IGM Resins), Omnirad (registered trademark) 819DW (product name, commercially available from IGM Resins), Omnirad (registered trademark) 907 (product name, commercially available from IGM Resins), Omnirad (registered trademark) TPO (product name, commercially available from IGM Resins), Omnirad (registered trademark) TPO-L (product name, commercially available from IGM Resins), Omnirad (registered trademark) 784 (product name, commercially available from IGM Resins), Irgacure (registered trademark) OXE01 (product name, commercially available from BASF Japan), Irgacure (registered trademark) OXE02 (product name, commercially available from BASF Japan), Irgacure (registered trademark) OXE03 (product name, commercially available from BASF Japan), and Irgacure (registered trademark) OXE04 (product name, commercially available from BASF Japan).

These photocuring initiators (C) can be used alone or two or more thereof can be appropriately used in combination.

In the present embodiment, when a chloroform solution containing 0.01 mass % of the photocuring initiator (C) is prepared and the absorbance of the chloroform solution containing 0.01 mass % of the photocuring initiator (C) is measured using active energy rays having a wavelength of 365 nm (i line), the absorbance is preferably 0.1 or more, and the photocuring initiator (C) exhibits very excellent absorbance. In addition, when the absorbance of a chloroform solution containing 0.01 mass % of the photocuring initiator (C) is measured using active energy rays having a wavelength of 405 nm (h line), the absorbance is preferably 0.1 or more, and very excellent absorbance is exhibited in this case. If the photocuring initiator (C) is used, for example, when a printed wiring board having a high-density and high-definition wiring form (pattern) is produced using a direct drawing exposure method, even when active energy rays having a wavelength of 405 nm (h line) are used, a photoradical reaction of maleimide occurs efficiently. Here, the absorbance at a wavelength of 365 nm (i line) is more preferably 0.15 or more because a resin composition with better photocurability can be obtained. The absorbance at a wavelength of 405 nm (h line) is more preferably 0.15 or more because a resin composition with better photocurability can be obtained. Here, the upper limits of the absorbance at a wavelength of 365 (i line) and the absorbance at a wavelength of 405 nm (h line) are, for example, 99.9 or less.

As the photocuring initiator (C), compounds represented by the following Formula (2) are preferable.

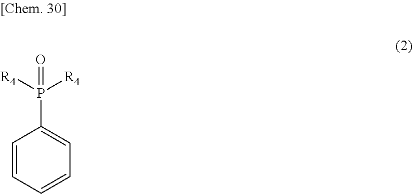

In Formula (2), R₄'s each independently indicate a substituent or phenyl group represented by the following Formula (3).

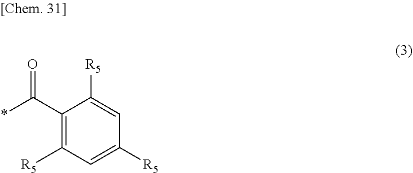

In Formula (3), R₅'s each independently indicate a hydrogen atom or a methyl group. In Formula (3), -* indicates a bond with a phosphorus atom (P) in Formula (2).

For the compound represented by Formula (2), when a chloroform solution containing 0.01 mass % of this compound is prepared, and the absorbance of the chloroform solution is measured using active energy rays having a wavelength of 365 nm (i line), the absorbance is 0.1 or more, and very excellent absorption for light with a wavelength of 365 nm (i line) is exhibited. Therefore, this compound suitably generates radicals for light with a wavelength of 365 nm (i line). The absorbance is preferably 0.15 or more. The upper limit value is, for example, 5.0 or less, and may be 10.0 or less.

In addition, for the compound represented by Formula (2), when a chloroform solution containing 0.01 mass % of this compound is prepared, and the absorbance of the chloroform solution is measured using active energy rays having a wavelength of 405 nm (h line), the absorbance is 0.1 or more and very excellent absorption for light with a wavelength of 405 nm (h line) is exhibited. Therefore, this compound suitably generates radicals for light with a wavelength of 405 nm (h line). The absorbance is preferably 0.15 or more. The upper limit value is, for example, 5.0 or less, and may be 10.0 or less.

In Formula (2), R₄'s each independently indicate a substituent or phenyl group represented by Formula (3). At least one of R₄ is preferably a substituent represented by Formula (3).

In Formula (3), R₅'s each independently indicate a hydrogen atom or a methyl group. At least one of R₅ is preferably a methyl group and all thereof are more preferably a methyl group.

Examples of compounds represented by Formula (2) include phosphine oxides such as 2,4,6-trimethylbenzoyl-diphenyl-phosphine oxide and bis(2,4,6-trimethylbenzoyl)-phenylphosphine oxide. Among these, bis(2,4,6-trimethylbenzoyl)-phenylphosphine oxide is preferable because it has excellent light transmittance. These compounds can be used alone or two or more thereof can be appropriately used in combination.

Acylphosphine oxides exhibit very excellent absorption for active energy rays having a wavelength of 405 nm (h line), and for example, a bismaleimide compound (A) having a transmittance of 5% or more at a wavelength of 405 nm (h line) can be suitably radically polymerized. Therefore, it is possible to preferably produce a resin composition which, particularly, when used in a multilayered printed wiring board, has excellent photocurability and can form a cured object having excellent heat resistance, thermal stability and insulation reliability in a well-balanced manner, a resin sheet, a multilayered printed wiring board using the same, and a semiconductor device.

In the resin composition, the content of the photocuring initiator (C) with respect to a total of 100 parts by mass of the bismaleimide compound (A), the resin or compound (B) and the photocuring initiator (C) is preferably 0.1 to 10 parts by mass, more preferably 1 to 8 parts by mass, and still more preferably 2 to 7 parts by mass because photocuring of the bismaleimide compound (A) and the resin or compound (B) is sufficiently advanced and better heat resistance and thermal stability are obtained.

### Filling Material

The resin composition of the present embodiment may contain a filling material (D) (also referred to as a component (D)) in order to improve various properties such as coating properties and heat resistance. As the filling material (D), a material that has insulation and does not inhibit transmittance with respect to various active energy rays used for photocuring is preferable, and a material that does not inhibit transmittance with respect to active energy rays having a wavelength of 365 nm (i line) and/or a wavelength of 405 nm (h line) is more preferable.

Examples of filling materials (D) include silica (for example, natural silica, fused silica, amorphous silica, and hollow silica, etc.), aluminum compounds (for example, boehmite, aluminum hydroxide, alumina, and aluminum nitride, etc.), boron compounds (for example, boron nitride, etc.), magnesium compounds (for example, magnesium oxide, and magnesium hydroxide, etc.), calcium compounds (for example, calcium carbonate, etc.), molybdenum compounds (for example, molybdenum oxide, and zinc molybdate, etc.), barium compounds (for example, barium sulfate, and barium silicate, etc.), talc (for example, natural talc, and calcined talc, etc.), mica, glass (for example, short fiber glass, spherical glass, fine powder glass, E glass, T glass, and D glass, etc.), silicone powder, fluororesin-based filling materials, urethane resin-based filling materials, (meth)acrylic resin-based filling materials, polyethylene-based filling materials, styrene-butadiene rubber, and silicone rubber. These filling materials (D) can be used alone or two or more thereof can be appropriately used in combination.

Among these, silica, boehmite, barium sulfate, silicone powder, fluororesin-based filling materials, urethane resin-based filling materials, (meth)acrylic resin-based filling materials, polyethylene-based filling materials, styrene-butadiene rubber, and silicone rubber are preferable.

These filling materials (D) may be surface-treated with a silane coupling agent to be described below or the like.

Silica is preferable, and fused silica is more preferable because the heat resistance of the cured object is improved and favorable coating properties are obtained. Specific examples of silica include SFP-130MC (product name, commercially available from Denka Co., Ltd.), and SC2050-MB (product name), SC1050-MLE (product name), YA010C-MFN (product name), and YA050C-MJA (product name) (which are commercially available from Admatechs).

The particle size of the filling material (D) is generally 0.005 to 10 μm, and preferably 0.01 to 1.0 μm in consideration of UV transmittance of the resin composition.

In the resin composition of the present embodiment, the content of the filling material (D) with respect to a total of 100 parts by mass of the bismaleimide compound (A), the resin or compound (B) and the photocuring initiator (C) is preferably 300 parts by mass or less, more preferably 200 parts by mass or less, and still more preferably 100 parts by mass or less because the light transmittance of the resin composition and the heat resistance of the cured object are improved. The upper limit value may be 30 parts by mass or less, 20 parts by mass or less or 10 parts by mass or less. Here, when the resin composition contains the filling material (D), the lower limit value is generally 1 part by mass with respect to a total of 100 parts by mass of the bismaleimide compound (A), the resin or compound (B) and the photocuring initiator (C) because an effect of improving various properties such as coating properties and heat resistance is obtained.

### Silane Coupling Agent and Wetting and Dispersing Agent

In the resin composition of the present embodiment, in order to improve dispersibility of the filling material, and the adhesive strength between the polymer and/or the resin and the filling material, a silane coupling agent and/or a wetting and dispersing agent can be used in combination.

These silane coupling agents are not limited as long as they are silane coupling agents that are generally used for a surface treatment of inorganic substances. Specific examples include aminosilane-based agents such as 3-aminopropyltrimethoxysilane, γ-aminopropyltriethoxysilane, 3-aminopropyldimethoxymethylsilane, 3-aminopropyldiethoxymethylsilane, N-β-(aminoethyl)-γ-aminopropyltrimethoxysilane, N-(2-aminoethyl)-3-aminopropyltriethoxysilane, N-(2-aminoethyl)-3-aminopropyldimethoxymethylsilane, N-(2-aminoethyl)-3-aminopropyldiethoxymethylsilane, N-phenyl-3-aminopropyltrimethoxysilane, N-phenyl-3-aminopropyltriethoxysilane, [3-(6-aminohexylamino)propyl]trimethoxysilane, and [3-(N,N-dimethylamino)-propyl]trimethoxysilane; epoxy silane-based agents such as γ-glycidoxypropyltrimethoxysilane, 3-glycidoxypropyltriethoxysilane, 3-glycidoxypropyldimethoxymethylsilane, 3-glycidoxypropyldiethoxymethylsilane, 2-(3,4-epoxycyclohexyl)ethyltrimethoxysilane, and [8-(glycidyloxy)-n-octyl]trimethoxysilane; vinyl silane-based agents such as vinyl tris(2-methoxyethoxy)silane, vinyltrimethoxysilane, vinyltriethoxysilane, dimethoxymethylvinylsilane, diethoxy methyl vinylsilane, trimethoxy(7-octen-1-yl)silane, and trimethoxy(4-vinylphenyl)silane; methacrylsilane-based agents such as 3-methacryloxypropyltrimethoxysilane, 3-methacryloxypropyltriethoxysilane, 3-methacryloxypropyldimethoxymethylsilane, and 3-methacryloxypropyldiethoxymethylsilane, and (meth)acrylic silanes such as γ-acryloxypropyltrimethoxysilane and 3-acryloxypropyltriethoxysilane; isocyanate silane-based agents such as 3-isocyanatopropyltrimethoxysilane and 3-isocyanatopropyltriethoxysilane; isocyanurate silane-based agents such as tris-(trimethoxysilylpropyl)isocyanurate; mercaptosilane-based agents such as 3-mercaptopropyltrimethoxysilane and 3-mercaptopropyldimethoxymethylsilane; ureidosilane-based agents such as 3-ureidopropyltriethoxysilane; styrylsilane-based agents such as p-styryltrimethoxysilane; cationic silane-based agents such as N-β-(N-vinylbenzylaminoethyl)-γ-aminopropyltrimethoxysilane hydrochloride; acid anhydride-based agents such as [3-(trimethoxysilyl)propyl]succinic anhydride; phenylsilane-based agents such as phenyltrimethoxysilane, phenyltriethoxysilane, dimethoxymethylphenylsilane, diethoxy methylphenylsilane, and p-tolyltrimethoxysilane; and arylsilane-based agents such as trimethoxy(1-naphthyl)silane. These silane coupling agents can be used alone or two or more thereof can be appropriately used in combination.

In the resin composition of the present embodiment, the content of the silane coupling agent is generally 0.1 to 10 parts by mass with respect to a total of 100 parts by mass of the bismaleimide compound (A), the resin or compound (B) and the photocuring initiator (C).

The wetting and dispersing agent is not particularly limited as long as it is a dispersion stabilizer used for paints. Specific examples include wetting and dispersing agents such as DISPERBYK (registered trademark)-110 (product name), 111 (product name), 118 (product name), 180 (product name), 161 (product name), and BYK (registered trademark)-W996 (product name), W9010 (product name), W903 (product name) (which are commercially available from BYK Japan). These wetting and dispersing agents can be used alone or two or more thereof can be appropriately used in combination.

In the resin composition of the present embodiment, the content of the wetting and dispersing agent is generally 0.1 to 10 parts by mass with respect to a total of 100 parts by mass of the bismaleimide compound (A), the resin or compound (B) and the photocuring initiator (C).

### Curing Accelerator

The resin composition of the present embodiment preferably contains a curing accelerator as necessary in order to appropriately adjust the curing rate. As the curing accelerator, those generally used as the curing accelerator such as a cyanic acid ester compound can be used. Examples of curing accelerators include organic metal salts such as zinc octoate, zinc naphthenate, cobalt naphthenate, copper naphthenate, iron acetylacetonate, nickel octylate, and manganese octylate; phenol compounds such as phenol, xylenol, cresol, resorcin, catechol, octyl phenol, and nonyl phenol; alcohols such as 1-butanol and 2-ethylhexanol; imidazoles such as 2-methylimidazole, 2-ethyl-4-methylimidazole, 2-phenylimidazole, 1-cyanoethyl-2-phenylimidazole, 1-cyanoethyl-2-ethyl-4-methylimidazole, 2-phenyl-4,5-dihydroxymethylimidazole, and 2-phenyl-4-methyl-5-hydroxymethylimidazole and derivatives such as adducts of carboxylic acids of these imidazoles or their acid anhydrides; amines such as dicyandiamide, benzyldimethylamine, and 4-methyl-N,N-dimethylbenzyl amine; phosphorus compounds such as phosphine compounds, phosphine oxide compounds, phosphonium salt compounds, and diphosphine compounds; epoxy-imidazole adduct compounds; peroxides such as benzoyl peroxide, p-chlorobenzoyl peroxide, di-t-butyl peroxide, diisopropyl peroxycarbonate, and di-2-ethylhexyl peroxycarbonate; and azo compounds such as 2,2′-azobisisobutyronitrile (hereinafter also referred to as “AIBN”). These curing accelerators can be used alone or two or more thereof can be appropriately used in combination.

In the resin composition of the present embodiment, the content of the curing accelerator is generally 0.1 to 20 parts by mass with respect to a total of 100 parts by mass of the bismaleimide compound (A), the resin or compound (B) and the photocuring initiator (C).

### Organic Solvent

The resin composition of the present embodiment may contain, as necessary, an organic solvent. When the organic solvent is used, it is possible to possible to adjust the viscosity when the resin composition is prepared. The type of the organic solvent is not particularly limited as long as it can dissolve a part or all of the resin in the resin composition. Examples of organic solvents include ketones such as acetone, methyl ethyl ketone, and methyl isobutyl ketone; alicyclic ketones such as cyclopentanone and cyclohexanone; cellosolve-based solvents such as propylene glycol monomethyl ether, and propylene glycol monomethyl ether acetate; ester-based solvents such as ethyl lactate, methyl acetate, ethyl acetate, butyl acetate, isoamyl acetate, methyl methoxypropionate, methyl hydroxyisobutyrate, and γ-butyrolactone; polar solvents such as amides, for example, dimethylacetamide and dimethylformamide; and non-polar solvents such as aromatic hydrocarbons, for example, toluene, xylene and anisole.

These organic solvents can be used alone or two or more thereof can be appropriately used in combination.

### Other Components

In the resin composition of the present embodiment, as long as properties of the present embodiment are not impaired, various polymer compounds such as thermally curable resins, thermoplastic resins, oligomers thereof, and elastomers not previously mentioned; flame retardant compounds not previously mentioned; additives and the like can be used in combination. These are not particularly limited as long as they are generally used. Examples of flame retardant compounds include nitrogen-containing compounds such as melamine and benzoguanamine, oxazine ring-containing compounds, phosphate compounds of phosphorus compounds, aromatic condensed phosphate esters, and halogen-containing condensed phosphate esters. Examples of additives include ultraviolet absorbers, antioxidants, fluorescent brightening agents, photosensitizers, dyes, pigments, thickeners, lubricants, antifoaming agents, surface conditioners, brightening agents, polymerization inhibitors, and thermosetting accelerators. These components can be used alone or two or more thereof can be appropriately used in combination.

In the resin composition of the present embodiment, the content of other components with respect to a total of 100 parts by mass of the bismaleimide compound (A), the resin or compound (B) and the photocuring initiator (C) is generally 0.1 to 10 parts by mass.

### Method of Producing Resin Composition

The resin composition of the present embodiment is prepared by appropriately mixing the bismaleimide compound (A), the resin or compound (B), the photocuring initiator (C), and as necessary, the filling material (D), other resins, other compounds, additives and the like. The resin composition can be suitably used as a varnish when a resin sheet of the present embodiment to be described below is prepared. Here, the organic solvent used for preparing a varnish is not particularly limited, and specific examples thereof are as described above.

Examples of methods of producing a resin composition include a method of sequentially blending the above components with a solvent and performing stirring sufficiently. The resin composition has excellent photocurability and the cured object obtained from the resin composition has excellent heat resistance, thermal stability, and insulation reliability.

During production of the resin composition, as necessary, known treatments (stirring, mixing, and kneading treatments, etc.) for uniformly dissolving or dispersing components can be performed. Specifically, when stirring and dispersing treatments are performed using a stirring tank with a stirrer having an appropriate stirring ability, it is possible to improve the dispersibility of the components in the resin composition. Stirring, mixing, and kneading treatments can be appropriately performed using known devices, for example, stirring devices for dispersion such as an ultrasonic homogenizer, devices for mixing three rollers, ball mills, bead mills, and sand mills, and revolution or rotation mixing devices. In addition, when the resin composition is prepared, an organic solvent can be used as necessary. The type of the organic solvent is not particularly limited as long as it can dissolve the resin in the resin composition, and specific examples thereof are as described above.

The resin composition can be suitably used as a varnish when a resin sheet of the present embodiment to be described below is prepared. A varnish can be obtained by a known method. For example, a varnish can be obtained by adding 10 to 900 parts by mass of an organic solvent with respect to 100 parts by mass of the components of the resin composition of the present embodiment excluding the organic solvent, and performing the known mixing treatments (stirring and kneading treatments, etc.).

### Applications

The resin composition can be preferably used for applications for which a resin composition with insulation reliability is required. It can be used for applications, for example, photosensitive films, photosensitive films with a support, prepregs, resin sheets, circuit substrates (laminate applications, multilayered printed wiring board applications, etc.), solder resists, underfill materials, die bonding materials, semiconductor encapsulation materials, hole-filling resins, and part-embedding resins. Among these, the resin composition can be suitably used for an insulating layer of a multilayered printed wiring board or for a solder resist because it has excellent photocurability, heat resistance and thermal stability.

### Cured Object

A cured object is obtained by curing the resin composition of the present embodiment. The cured object can be obtained, for example, by melting a resin composition or dissolving a resin composition in a solvent, then pouring it into a mold, and curing it under general conditions using light. For a light wavelength range, curing is preferably performed in a range of 100 to 500 nm in which curing proceeds more efficiently using a photopolymerization initiator or the like.

### Resin Sheet

A resin sheet of the present embodiment is a resin sheet with a support including a support and a resin layer that is disposed on one surface or both surfaces of the support, and the resin layer contains a resin composition. A resin sheet can be produced by applying a resin composition onto a support and drying it. The resin layer in the resin sheet has excellent heat resistance, thermal stability and insulation reliability.

Known supports can be used, and a resin film is preferable. Examples of resin films include a polyimide film, polyamide film, polyester film, polyethylene terephthalate (PET) film, polybutylene terephthalate (PBT) film, polypropylene (PP) film, polyethylene (PE) film, polyethylene naphthalate film, polyvinyl alcohol film, and triacetyl acetate film. Among these, a PET film is preferable.

In order to facilitate peeling off from the resin layer, it is preferable to apply a release agent to the surface of the resin film. The thickness of the resin film is preferably in a range of 5 to 100 μm and more preferably in a range of 10 to 50 μm. If the thickness is less than 5 μm, the support tends to break when the support is peeled off before development, and if the thickness is more than 100 μm, the resolution when exposed from above the support tends to decrease.

In addition, in order to reduce scattering of light during exposure, it is preferable that the resin film have excellent transparency.

In addition, in the resin sheet of the present embodiment, the resin layer may be protected with a protective film.

When the side of the resin layer is protected with a protective film, it is possible to prevent dust from adhering to or scratching the surface of the resin layer. As the protective film, a film made of the same material as the resin film can be used. The thickness of the protective film is preferably in a range of 1 to 50 μm and more preferably in a range of 5 to 40 μm. If the thickness is less than 1 μm, handling properties of the protective film tend to deteriorate, and if the thickness is more than 50 μm, the cost tends to increase. Here, for the protective film, it is preferable that the adhesive strength between the resin layer and the protective film be smaller than the adhesive strength between the resin layer and the support.

Examples of methods of producing a resin sheet of the present embodiment include a method of producing a resin sheet by applying the resin composition of the present embodiment to a support such as a PET film, drying it, and removing an organic solvent.

Coating can be performed by known methods using, for example, a roll coater, a comma coater, a gravure coater, a die coater, a bar coater, a lip coater, a knife coater, a squeeze coater or the like. Drying can be performed, for example, by a method of heating in a dryer at 60 to 200° C. for 1 to 60 minutes.

The amount of the organic solvent remaining in the resin layer is preferably 5 mass % or less with respect to a total mass of the resin layer in order to prevent diffusion of the organic solvent in subsequent processes. The thickness of the resin layer is preferably 1 to 50 μm in order to improve handling properties.

The resin sheet can be preferably used for producing the insulating layer of the multilayered printed wiring board.

### Multilayered Printed Wiring Board

The multilayered printed wiring board of the present embodiment has an insulating layer and a conductor layer that is formed on one surface or both surfaces of the insulating layer, and the insulating layer contains the resin composition. The insulating layer can be obtained, for example, by laminating one or more resin sheets and curing them. The number of insulating layers and conductor layers laminated is not particularly limited, and the number of laminations can be appropriately set according to desired applications. In addition, the order of the insulating layer and the conductor layer is not particularly limited. The conductor layer may be a metal foil used for various printed wiring board materials, and examples thereof include metal foils of copper, aluminum and the like. Examples of copper metal foils include copper foils such as a rolled copper foil and an electrolytic copper foil. The thickness of the conductor layer is generally 1 to 100 μm. Specifically, the following method can be used for production.

### Laminating Process

In the laminating process, the side of the resin layer of the resin sheet is laminated on one surface or both surfaces of the circuit substrate using a vacuum laminator. Examples of circuit substrates include glass epoxy substrates, metal substrates, ceramic substrates, silicon substrates, semiconductor sealing resin substrates, polyester substrates, polyimide substrates, BT resin substrates, and thermosetting polyphenylene ether substrates. Here, the circuit substrate is a substrate in which a patterned conductor layer (circuit) is formed on one surface or both surfaces of the substrate. In addition, in a multilayered printed wiring board in which conductor layers and insulating layers are alternately laminated, the circuit substrate also includes a substrate in which one surface or both surfaces of the outermost layer of a multilayered printed wiring board are patterned conductor layer (circuit). Here, the insulating layer laminated on the multilayered printed wiring board may be an insulating layer obtained by laminating one or more resin sheets of the present embodiment and curing them or an insulating layer obtained by laminating one or more resin sheets of the present embodiment and one or more known resin sheets different from the resin sheet of the present embodiment. Here, the method of laminating resin sheets of the present embodiment and known resin sheets different from the resin sheets of the present embodiment is not particularly limited. The surface of the conductor layer may be roughened in advance by a blacking treatment and/or copper etching. In the laminating process, when the resin sheet has a protective film, the protective film is peeled off and removed, the resin sheet and the circuit substrate are then preheated as necessary, and the resin layer of the resin sheet is compressed to the circuit substrate while pressing and heating. In the present embodiment, a method of laminating a resin layer of a resin sheet on a circuit substrate under a reduced pressure by a vacuum lamination method is suitably used.

For conditions for the laminating process, for example, it is preferable to perform laminating at a compressing temperature (laminating temperature) of 50 to 140° C., a compressing pressure of 1 to 15 kgf/cm², a compressing time of 5 to 300 seconds, and an air pressure of 20 mmHg or less under a reduced pressure. In addition, the laminating process may be a batch type process or a continuous type process using a roller. The vacuum lamination method can be performed using a commercially available vacuum laminator. Examples of commercially available vacuum laminators include a 2-stage build-up laminator (product name, commercially available from Nikko-Materials Co., Ltd.).

### Exposure Process

In the exposure process, a resin layer is provided on the circuit substrate according to the laminating process, and active energy rays as a light source are then emitted to a predetermined part of the resin layer, and the resin layer in the emitted part is cured.

Emission may be performed through a mask pattern, or a direct drawing method for direct emission may be used. Examples of active energy rays include ultraviolet rays, visible light, electron beams, and X-rays. The wavelength of active energy rays is, for example, in a range of 200 to 600 nm. When ultraviolet rays are used, the amount of emission is roughly 10 to 1,000 mJ/cm². In addition, when a printed wiring board having a high-density and high-definition wiring form (pattern) is produced using a stepper exposure method, as the active energy rays, for example, active energy rays having a wavelength of 365 nm (i line) are preferably used. When active energy rays having a wavelength of 365 nm (i line) are used, the amount of emission is roughly 10 to 10,000 mJ/cm². When a printed wiring board having a high-density and high-definition wiring form (pattern) is produced using a direct drawing exposure method, as the active energy rays, for example, active energy rays having a wavelength of 405 nm (h line) are preferably used. When active energy rays having a wavelength of 405 nm (h line) are used, the amount of emission is roughly 10 to 10,000 mJ/cm².

The method of exposure through a mask pattern includes a contact exposure method in which the mask pattern is brought into close contact with the multilayered printed wiring board and a non-contact exposure method in which parallel light beams are used for exposure without close contact, and any method may be used. In addition, when a support is present on the resin layer, exposure may be performed from above the support or exposure may be performed after the support is peeled off.

### Developing Process

In the present embodiment, as necessary, a developing process may be included.

That is, when there is no support on the resin layer, after the exposure process, a part (unexposed part) that is not photocured in wet development is removed and developed, and thus a pattern of the insulating layer can be formed. In addition, when there is a support on the resin layer, after the exposure process, the support is removed, a part (unexposed part) that is not photocured in wet development is then removed and developed, and thus a pattern of the insulating layer can be formed.

In the case of wet development, the developing solution is not particularly limited as long as it selectively dissolves the unexposed part. For example, organic solvents such as cyclohexanone, cyclopentanone, and γ-butyrolactone; alkaline developing solutions such as tetramethylammonium hydroxide aqueous solutions, sodium carbonate aqueous solutions, potassium carbonate aqueous solutions, sodium hydroxide aqueous solutions, and potassium hydroxide aqueous solutions are used. These developing solutions can be used alone or two or more thereof can be appropriately used in combination.

In addition, as the development method, known methods, for example, dipping, paddle, spray, rocking immersion, brushing, and scrapping, can be performed. In pattern formation, as necessary, these development methods may be used in combination. In addition, as the development method, high-pressure spray is preferably used because the resolution is further improved. When the spray method is used, the spray pressure is preferably 0.02 to 0.5 MPa.

### Post-Baking Process

After the exposure process is completed or the developing process is completed, a post-baking process is performed to form an insulating layer (cured object). Examples of post-baking processes include an ultraviolet ray emitting process using a high-pressure mercury lamp and a heating process using a clean oven, and these can be used in combination. When ultraviolet rays are emitted, as necessary, the amount of emission can be adjusted, and for example, emission can be performed at an amount of emission of about 50 to 10,000 mJ/cm². In addition, heating conditions can be appropriately selected as necessary, and a range of 150 to 220° C. and 20 to 180 minutes is preferably selected and a range of 160 to 200° C. and 30 to 150 minutes is more preferably selected.

### Conductor Layer Forming Process

After the insulating layer (cured object) is formed, the conductor layer is formed on the surface of the insulating layer by dry plating. As the dry plating, known methods such as a vapor deposition method, a sputtering method, and an ion plating method can be used. In the vapor deposition method (vacuum vapor deposition method), for example, a multilayered printed wiring board is put into a vacuum container, a metal is heated and evaporated, and thus a metal film can be formed on the insulating layer. In the sputtering method, for example, a multilayered printed wiring board is put into a vacuum container, an inert gas such as argon is introduced, a DC voltage is applied, the ionized inert gas collides with a target metal, and a metal film can be formed on the insulating layer by the metal that has been hit.

Next, a conductor layer is formed by electroless plating, electrolytic plating or the like. As a method of subsequent pattern formation, for example, a subtractive method, a semi-additive method or the like can be used.

### Sealing Material

The sealing material of the present embodiment contains the resin composition of the present embodiment. A method of producing a sealing material is not particularly limited, and generally known methods can be appropriately applied. For example, a sealing material can be produced by mixing the resin composition of the present embodiment, various known additives or solvents that are generally used for sealing material applications, and the like using a known mixer. Here, during mixing, a method of adding the maleimide compound of the present embodiment, various additives, and a solvent is not particularly limited, and generally known methods can be appropriately applied.

### Fiber-Reinforced Composite Material

The fiber-reinforced composite material of the present embodiment includes the resin composition of the present embodiment and reinforcing fibers. As the reinforcing fibers, generally known fibers can be used and the present invention is not particularly limited. Examples thereof include glass fibers such as E glass, D glass, L glass, S glass, T glass, Q glass, UN glass, NE glass, and spherical glass; carbon fibers; aramid fibers; boron fibers; PBO fibers; high-strength polyethylene fibers; alumina fibers; and silicon carbide fibers. The form and arrangement of reinforcing fibers are not particularly limited, and can be appropriately selected from among woven fabrics, non-woven fabrics, mats, knits, braids, unidirectional strands, rovings, chopped and the like. In addition, preforms (those obtained by laminating woven fabrics made of reinforcing fibers, those obtained by stitching and integrating them with stitch threads, or fiber structures such as three-dimensional woven fabrics and braids) as forms of reinforcing fibers can be applied.

A method of producing such a fiber-reinforced composite material is not particularly limited and generally known methods can be appropriately applied. Examples thereof include a liquid⋅composite⋅molding method, a resin⋅film⋅infusion method, a filament⋅winding method, a hand⋅lay-up method, and a pultrusion method. Among these, the resin⋅transfer⋅molding method, which is one liquid⋅composite⋅molding method, can be used for various applications because materials other than preforms such as metal plates, foam cores, and honeycomb cores can be set in advance in the mold, and is preferably used when composite materials with relatively complex shapes are mass-produced in a short time.

### Adhesive

An adhesive of the present embodiment contains the resin composition of the present embodiment. A method of producing an adhesive is not particularly limited, and generally known methods can be appropriately applied. For example, an adhesive can be produced by mixing the resin composition of the present embodiment, various known additives generally used in adhesive applications, a solvent and the like using a known mixer. Here, during mixing, a method of adding the maleimide compound of the present embodiment, various additives, and a solvent is not particularly limited, and generally known methods can be appropriately applied.

### Semiconductor Device

A semiconductor device of the present embodiment contains the resin composition. Specifically, it can be produced by the following method. A semiconductor device can be produced by mounting a semiconductor chip on a conduction part of the multilayered printed wiring board. Here, the conduction part is a part of the multilayered printed wiring board that transmits an electronic signal, and the part may be a surface or an embedded part. In addition, the semiconductor chip is not particularly limited as long as it is an electric circuit element made of a semiconductor.

The method of mounting a semiconductor chip when the semiconductor device is produced is not particularly limited as long as the semiconductor chip functions effectively. Specific examples thereof include a wire bonding mounting method, a flip-chip mounting method, a mounting method using a bumpless build-up layer (BBUL), a mounting method using an anisotropic conductive film (ACF) and a mounting method using a non-conductive film (NCF).

In addition, a semiconductor device can be produced by forming an insulating layer containing a resin composition on a semiconductor chip or a substrate on which a semiconductor chip is mounted. The shape of the substrate on which a semiconductor chip is mounted may be a wafer shape or a panel shape. After formation, the same method as in the multilayered printed wiring board can be used for production.

### EXAMPLES

Hereinafter, the present embodiment will be described in more detail with reference to examples and comparative examples. The present embodiment is not limited to the following examples.

Molecular weight measurement conditions are as follows.
model: GPC TOSOH HLC-8220GPC
column: Super HZM-N
eluent: THF (tetrahydrofuran); 0.35 ml/min, 40° C.
detector: RI (differential refractometer)
molecular weight standard: polystyrene

### Synthesis of Bismaleimide Compound

### Synthesis Example 1

100 g of toluene and 33 g of N-methylpyrrolidone were put into a 500 ml round bottom flask with a fluororesin-coated stirring bar. Next, 80.2 g (0.16 mol) of PRIAMINE 1075 (commercially available from Croda Japan) was added and 14.4 g (0.16 mol) of methanesulfonic anhydride was then slowly added to form a salt. Stirring was performed for about 10 minutes for mixing, and 4-(2,5-dioxotetrahydrofuran-3-yl)-1,2,3,4-tetrahydronaphthalene-1,2 dicarboxylic anhydride (22.5 g, 0.08 mol) was then slowly added to the stirred mixture. A Dean-Stark apparatus and a condenser were attached to the flask. The mixture was heated to reflux for 6 hours to form an amine-terminated diimide. The theoretical amount of water produced from this condensation was obtained by this time. The reaction mixture was cooled to room temperature or lower and 17.6 g (0.19 mol) of maleic anhydride was added to the flask. The mixture was additionally refluxed for 8 hours to obtain an expected amount of produced water. The mixture was cooled to room temperature and 200 ml of toluene was then added to the flask. Next, the diluted organic layer was washed with water (100 ml×3 times) to remove salts and unreacted raw materials. Then, the solvent was removed under vacuum to obtain 104 g of a dark amber liquid bismaleimide compound (a yield of 93%, Mw=3,700) (A-1).

### Comparative Synthesis Example 1

110 g of toluene and 36 g of N-methylpyrrolidone were put into a 500 ml round bottom flask with a fluororesin-coated stirring bar. Next, 90.5 g (0.17 mol) of PRIAMINE 1075 (commercially available from Croda Japan) was added and 16.3 g (0.17 mol) of methanesulfonic anhydride was then slowly added to form a salt. Stirring was performed for about 10 minutes for mixing, and 1,2,4,5-cyclohexanetetracarboxylic dianhydride (18.9 g, 0.08 mol) was then slowly added to the stirred mixture. A Dean-Stark apparatus and a condenser were attached to the flask. The mixture was heated to reflux for 6 hours to form an amine-terminated diimide. The theoretical amount of water produced from this condensation was obtained by this time. The reaction mixture was cooled to room temperature or lower, and 19.9 g (0.20 mol) of maleic anhydride was added to the flask. The mixture was additionally refluxed for 8 hours to obtain an expected amount of produced water. The mixture was cooled to room temperature and 200 ml of toluene was then added to the flask. Next, the diluted organic layer was washed with water (100 mlx3 times) to remove salts and unreacted raw materials. Then, the solvent was removed under vacuum to obtain 110 g of an amber wax bismaleimide compound (a yield of 92%, Mw=3,000) (A′-3).

### Synthesis of Cyanic Acid Ester Compound

### Synthesis Example 2

0.47 mol (in terms of OH groups) of an a-naphthol aralkyl type phenolic resin (SN495V (product name) commercially available from Nippon Steel Chemical & Material, OH group equivalent: 236 g/eq., including a naphthol aralkyl with a number n of repeating units of 1 to 5) was dissolved in 500 mL of chloroform and 0.7 mol of triethylamine was added to this solution (Solution 1).

While the temperature was maintained at -10° C., Solution 1 was added dropwise to 300 g of a chloroform solution containing 0.93 mol of cyanogen chloride over 1.5 hours, and after dropwise addition was completed, the mixture was stirred for 30 minutes.

After that, a mixed solution containing 0.1 mol of trimethylamine and 30 g of chloroform was added dropwise into a reaction container, the mixture was stirred for 30 minutes, and the reaction was completed. The by-produced trimethylamine hydrochloride was filtered off from the reaction solution, the obtained filtrate was then washed with 500 mL of 0.1 N hydrochloric acid, washing with 500 mL of water was then repeated four times. The sample was dried with sodium sulfate and then evaporated at 75° C., and additionally degassed under a reduced pressure at 90° C. to obtain a brown solid α-naphthol aralkyl type cyanic acid ester resin (SNCN, Formula (28), including one having n₁₈ of 1 to 4) (B-2). When the obtained α-naphthol aralkyl type cyanic acid ester resin was analyzed using infrared absorption spectrums, absorption of the cyanic acid ester group near 2,264 cm⁻¹ was confirmed.

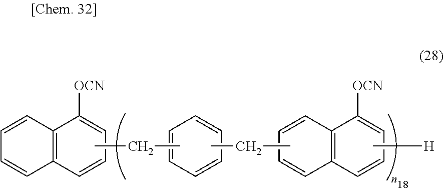

### Synthesis of Compound Having Ethylenically Unsaturated Group

### Synthesis Example 3

225 g of XD-1000 (commercially available from Nippon Kayaku Co., Ltd., a softening point of 74.8° C., and an epoxy equivalent 255 g/eq.), 72.1 g of acrylic acid, 3 g of triphenylphosphine as a catalyst, and propylene glycol monomethyl ether monoacetate as a solvent were put into a flask including a thermometer, a cooling pipe, and a stirrer so that the solid component content was 80%, the mixture was reacted at 100° C. for 24 hours to obtain an epoxy carboxylate compound solution as a reaction intermediate.

Subsequently, 140 g of 1,2,3,6-tetrahydrophthalic anhydride (THPA) (product name: RIKACID TH, commercially available from New Japan Chemical Co., Ltd.) as a polybasic acid anhydride was added to the obtained reactive epoxy carboxylate compound solution, propylene glycol monomethyl ether monoacetate was added as a solvent so that the solid component content was 65%, and the mixture was reacted at 100° C. for 6 hours to obtain a compound (B-6) having an ethylenically unsaturated group. The solid component acid value (AV: mg KOH/g) of the obtained compound (B-6) having an ethylenically unsaturated group was 110.

Materials used in this example are shown.

### Bismaleimide Compound (A)

(A-1) bismaleimide resin including a constituent unit represented by General Formula (1) and maleimide groups at both ends of a molecular chain bismaleimide resin A-1 of Synthesis Example 1 (compound represented by the following Formula (3), high-viscosity liquid at 25° C.)

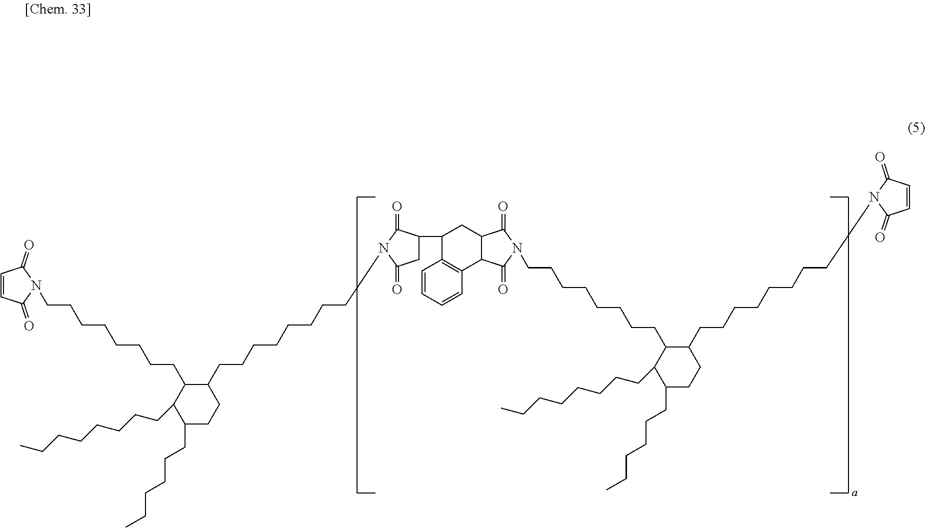

In Formula (5), a indicates an integer of 1 to 10. a is preferably an integer of 1 to 6 because a more suitable viscosity can be obtained and an increase in viscosity of the varnish can be better controlled.

### Bismaleimide Compound (A′) That Does Not Satisfy General Formula (1)

(A′-1) BMI-2300 (polyphenylmethane maleimide, compound represented by the following Formula (29), solid at 25° C., commercially available from Daiwa Fine Chemicals Co., Ltd.)
(A′-2) BMI-3000 (compound represented by the following Formula (14), solid at 25° C., commercially available from DESIGNER MOLECURES Inc.)
(A′-3) Comparative Synthesis Example 1 (compound represented by the following Formula (30), liquid at 25° C.)

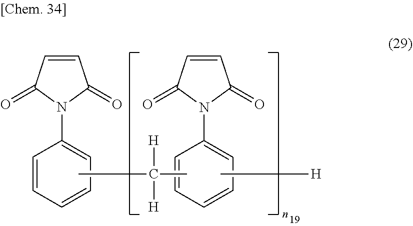

In Formula (29), n₁₉ indicates an integer of 1 or more, preferably an integer of 1 to 10, and more preferably an integer of 1 to 5.

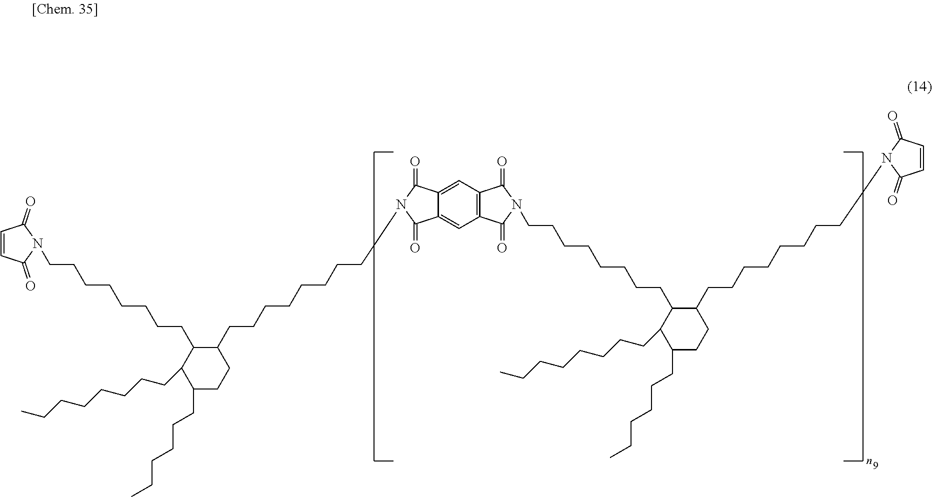

In Formula (14), n₉ indicates an integer of 1 or more, and preferably an integer of 1 to 10.

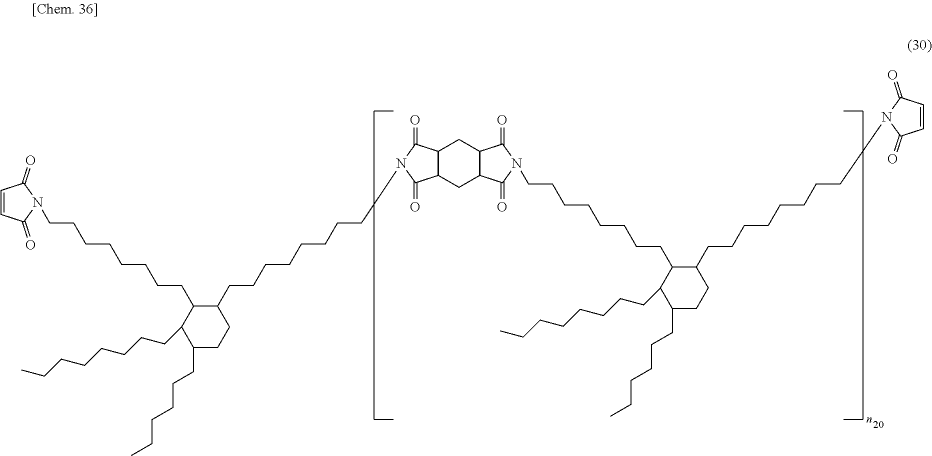

In Formula (30), neo indicates an integer of 1 or more, and preferably an integer of 1 to 6.

### Resin or Compound (B)

(B-1) bismaleimide resin MIR-5,000 (compound represented by the following Formula (31), solid at 25° C., commercially available from Nippon Kayaku Co., Ltd.)
(B-2) α-naphthol aralkyl type cyanic acid ester resin obtained in Synthesis Example 2 (SNCN, cyanic acid ester resin)
(B-3) P-d type benzoxazine compound (3,3′-(methylene-1,4-diphenylene)bis(3,4-dihydro-2H-1,3-benzoxazine), benzoxazine compound, commercially available from Shikoku Chemical Corporation,)
(B-4) biphenyl aralkyl type epoxy resin (NC-3000H (product name), epoxy resin, commercially available from Nippon Kayaku Co., Ltd.)
(B-5) carbodiimide compound (Carbodilite B-01 (product name), commercially available from Nisshinbo Chemical Inc.)
(B-6) acid-modified dicyclopentadiene phenol type epoxy acrylate compound obtained in Synthesis Example 3 (KAYARAD (registered trademark) ZXR-1889H (product name), compound having an ethylenically unsaturated group commercially available from Nippon Kayaku Co., Ltd.)

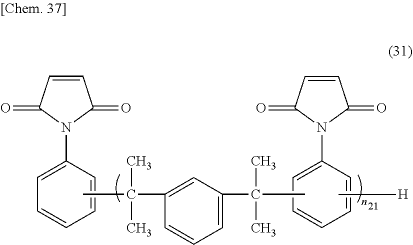

In Formula (31), n₂₁ indicates an integer of 1 to 10.

### Photopolymerization Initiator (C)

(C-1) bis(2,4,6-trimethylbenzoyl)-phenylphosphine oxide (Omnirad (registered trademark) 819 (product name) commercially available from IGM Resins)
(C-2) 2-benzyl-2-dimethylamino-1-(4-morpholinophenyl)-butanone-1 (Omnirad (registered trademark) 369 (product name) commercially available from IGM Resins)
(C-3) 2-methyl-1-[4-(methylthio)phenyl]-2-morpholinopropan-1-one (Omnirad (registered trademark) 907 (product name) commercially available from IGM Resins)

### Evaluation of Resin Composition

The resin compositions of Examples 1 to 8 and Comparative Examples 1 to 3 were evaluated as follows. The results are summarized in Table 1.

### Sensitivity

The photosensitive resin compositions obtained in Examples 1 to 8 and Comparative Examples 1 to 3 were applied onto a copper-clad laminate (ELC4762, commercially available from Sumitomo Bakelite Co., Ltd.) using an applicator, and heated at a temperature of 80° C. for 30 minutes to form a coating film having a film thickness of 20 μm. Then, using a light source that can emit active energy rays having a wavelength of 405 nm (h line) (ultra-high pressure mercury lamp USH-500BY1 (product name), commercially available from USHIO), using a 21-step tablet, exposure was performed using a projection exposure machine at an exposure amount such that the number of steps remaining after development was 7.

The sensitivity was evaluated based on the following criteria, and the evaluation results are shown in Table 1.

### Evaluation Criteria

⊚: 7 steps remaining at an exposure amount of less than 500 mJ/cm²
O: 7 steps remaining at an exposure amount of 500 mJ/cm² or more and less than 1,000 mJ/cm²
Δ: 7 steps remaining at an exposure amount of 1,000 mJ/cm² or more and less than 3,000 mJ/cm²
x: not cured even at an exposure amount of 3,000 mJ/cm² or more

### Tensile Elastic Modulus

First, the photosensitive resin composition obtained in each of examples and comparative examples was applied onto an ultra-low-roughness electrolytic copper foil having a thickness of 12 μm (CF-T4X-S V (product name), commercially available from Fukuda Metal Foil & Powder Co., Ltd.) using an applicator and then dried at a temperature of 80° C. for 30 minutes to form a film-like photosensitive resin composition on the copper foil. The coating thickness of the photosensitive resin composition was adjusted so that the film thickness of the film-like photosensitive resin composition after drying was 20 μm. The film-like photosensitive resin composition was exposed in an exposure amount of 3,000 mJ/cm² using a light source (ultra-high pressure mercury lamp 500 W multi-light (product name), commercially available from USHIO) that can emit active energy rays having a wavelength of 405 nm (h line), and then heated and cured at a temperature of 180° C. for 60 minutes, and the copper foil was then removed by etching to obtain a cured film.

Next, the obtained cured film was cut out to a test piece of 6 cm×5 mm and the tensile elastic modulus (MPa) and the elongation at break (%) were measured using a tensile test instrument (product name “RTG-1201” commercially available from A&D Co., Ltd.) at 25° C. and a rate of 5 mm/min.

### Dielectric Characteristics

The copper foil of the copper foil laminate was removed by etching and dried at 130° C. for 30 minutes, and the cured object of the resin film was then cut out to prepare a test piece of 10 cm×5 cm. The specific dielectric constant and the dielectric tangent at 10 GHz of the obtained test piece were measured using a cavity resonator method dielectric constant measurement device (commercially available from AET, Inc.). After the measurement, the test piece was immersed in water for 24 hours to absorb the water and then taken out of the water and the water was wiped off, it was left in a 30% environment at 25° C. for one day, and the specific dielectric constant and the dielectric tangent at 10 GHz were then measured again.

### Glass Transition Temperature

The copper foil on both surfaces of the copper foil laminate was removed by etching and dried at 130° C. for 30 minutes, and the cured object of the resin film was then cut out to prepare a test piece of 5 cm×5 mm. The obtained test piece was measured using a dynamic viscoelasticity test instrument (DMA: product name “RSA-G2,” commercially available from TA Instruments), and the temperature at which tan δ was the maximum value was determined as the glass transition temperature.

### Water Absorption Rate

The copper foil on both surfaces of the copper foil laminate was removed by etching and dried at 130° C. for 30 minutes, and the cured object of the resin film was then cut out to prepare a test piece of 10 cm×5 cm. The obtained test piece was immersed in water for 24 hours to absorb water and then taken out from water and water was wiped off, and the weight increase rate of the test piece was then used as the water absorption rate.

### HAST Resistance

Each composition was applied onto Espanex M series in which comb patterns of L/S=100 μm/100 μm were formed by a screen printing method to a thickness of 25 μm (commercially available from Nippon Steel Chemical & Material: a base imide thickness of 25 μm, a Cu thickness of 18 μm), and the coating film was dried in a hot air dryer at 80° C. for 60 minutes. Next, a test substrate for HAST evaluation was obtained by covering the resin surface with AFLEX (Grade: 25N NT) (commercially available from AGC) and heating at 220° C. for 2 hours. The electrode part of the obtained substrate was subjected to wiring connection by soldering and left in an environment at 130° C. and 85% RH, and a voltage of 100 V was applied, and the time until the resistance value became 1×10⁸ Ω or less was measured.
O . . . 300 hours or longer
Δ. . . 30 to 300 hours
x . . . 30 hours or shorter

TABLE 1

| | | Example | | | | | |
|---|---|---|---|---|---|---|---|
| Component | Material | 1 | 2 | 3 | 4 | 5 | 6 |
| Bismaleimide | A-1 | 85 | 85 | 85 | 85 | 85 | 85 |
| compound (A) | A′-1 | | | | | | |
| | A′-2 | | | | | | |
| | A′-3 | | | | | | |
| Resin or | B-1 | 10 | | | | | |
| compound(B) | Bismaleimide | | | | | | |
| | compound | | | | | | |
| | B-2 Cyanic acid | | 10 | | | | |
| | ester resin | | | | | | |
| | B-3 | | | 10 | | | |
| | Benzoxazine | | | | | | |
| | compound | | | | | | |
| | B-4 Epoxy resin | | | | 10 | | |
| | B-5 | | | | | 10 | |
| | Carbodiimide | | | | | | |
| | compound | | | | | | |
| | B-6 Compound | | | | | | 10 |
| | having an | | | | | | |
| | ethylenically | | | | | | |
| | unsaturated | | | | | | |
| | group | | | | | | |
| Photopolymerization | C-1 Omnirad | 5 | 5 | 5 | 5 | 5 | 5 |
| initiator (C) | 819 | | | | | | |
| | C-2 Omnirad | | | | | | |
| | 369 | | | | | | |
| | C-3 Omnirad | | | | | | |
| | 907 | | | | | | |
| Solvent | Toluene | 30 | 30 | 30 | 30 | 30 | 30 |
| Photocurability | Sensitivity | ⊚ | ⊚ | ⊚ | ⊚ | ⊚ | ⊚ |
| | (m · J/cm²) | | | | | | |
| Dielectric | Dielectric | 2.2 | 2.3 | 2.3 | 2.4 | 2.3 | 2.5 |
| characteristics | constant Dk | | | | | | |
| | Dielectric | 0.0032 | 0.0034 | 0.0034 | 0.0043 | 0.0035 | 0.0044 |
| | tangent Df | | | | | | |
| | Dielectric | 2.2 | 2.3 | 2.3 | 2.5 | 2.3 | 2.5 |
| | constant Dk | | | | | | |
| | after water | | | | | | |
| | absorption | | | | | | |
| | Dielectric | 0.0033 | 0.0034 | 0.0035 | 0.0048 | 0.0035 | 0.0050 |
| | tangent Df after | | | | | | |
| | water absorption | | | | | | |
| Mechanical | Tensile elastic | 675 | 710 | 688 | 632 | 540 | 607 |
| properties | modulus (MPa) | | | | | | |
| | Elongation at | 72 | 68 | 69 | 70 | 73 | 71 |
| | break (%) | | | | | | |
| Heat resistance | Tg (° C.) | 111 | 114 | 110 | 96 | 92 | 98 |
| Insulation reliability | Water | 0.05 | 0.05 | 0.06 | 0.18 | 0.04 | 0.16 |
| | absorption rate | | | | | | |
| | (%) | | | | | | |
| | HAST | ◯ | ◯ | ◯ | ◯ | ◯ | ◯ |
| | resistance | | | | | | |

| | | Example | | Comparative Example | | |
|---|---|---|---|---|---|---|
| Component | Material | 7 | 8 | 1 | 2 | 3 |
| Bismaleimide | A-1 | 85 | 85 | | | |
| compound (A) | A′-1 | | | 85 | | |
| | A′-2 | | | | 85 | |
| | A′-3 | | | | | 85 |
| Resin or | B-1 | 10 | 10 | 10 | 10 | 10 |
| compound(B) | Bismaleimide | | | | | |
| | compound | | | | | |
| | B-2 Cyanic acid | | | | | |
| | ester resin | | | | | |
| | B-3 | | | | | |
| | Benzoxazine | | | | | |
| | compound | | | | | |
| | B-4 Epoxy resin | | | | | |
| | B-5 | | | | | |
| | Carbodiimide | | | | | |
| | compound | | | | | |
| | B-6 Compound | | | | | |
| | having an | | | | | |
| | ethylenically | | | | | |
| | unsaturated | | | | | |
| | group | | | | | |
| Photopolymerization | C-1 Omnirad | | | 5 | 5 | 5 |
| initiator (C) | 819 | | | | | |
| | C-2 Omnirad | 5 | | | | |
| | 369 | | | | | |
| | C-3 Omnirad | | 5 | | | |
| | 907 | | | | | |
| Solvent | Toluene | 30 | 30 | | | 30 |
| Photocurability | Sensitivity | ◯ | ◯ | X *1 | ◯ | ⊚ |
| | (m · J/cm²) | | | | | |
| Dielectric | Dielectric | 2.2 | 2.2 | — *2 | 2.4 | 2.3 |
| characteristics | constant Dk | | | | | |
| | Dielectric | 0.0035 | 0.0036 | — *2 | 0.0035 | 0.0034 |
| | tangent Df | | | | | |
| | Dielectric | 2.2 | 2.2 | — *2 | 2.4 | 2.3 |
| | constant Dk | | | | | |
| | after water | | | | | |
| | absorption | | | | | |
| | Dielectric | 0.0037 | 0.0038 | — *2 | 0.00522 | 0.0054 |
| | tangent Df after | | | | | |
| | water absorption | | | | | |
| Mechanical | Tensile elastic | 666 | 658 | — *2 | 520 | 470 |
| properties | modulus (MPa) | | | | | |
| | Elongation at | 67 | 66 | — *2 | 58 | 51 |
| | break (%) | | | | | |
| Heat resistance | Tg (° C.) | 108 | 106 | — *2 | 86 | 77 |
| Insulation reliability | Water | 0.05 | 0.06 | — *2 | 0.34 | 0.23 |
| | absorption rate | | | | | |
| | (%) | | | | | |
| | HAST | ◯ | ◯ | — *2 | Δ | Δ |
| | resistance | | | | | |

*1: no cured film was obtained even with an exposure of 3,000 m · J/cm²
*2: not measured because no cured film was obtained.

As can be clearly understood from Table 1, according to the present embodiment, even when exposed to any ray of active energy rays having a wavelength of 200 to 600 nm, photosensitivity was good and photocuring was possible.

In addition, it was confirmed that the resin compositions of Examples 1 to 8 had, as properties of the cured object thereof, low-dielectric characteristics, a small change in dielectric characteristics after water absorption, low elasticity, high elongation, high heat resistance, a low water absorption rate, and excellent insulation reliability.

### INDUSTRIAL APPLICABILITY

Since the resin composition of the present embodiment has excellent photocurability and alkaline developability, it is industrially beneficial and can be used for applications, for example, photosensitive films, photosensitive films with a support, prepregs, resin sheets, circuit substrates (laminate applications, multilayered printed wiring board applications, etc.), solder resists, underfill materials, die bonding materials, semiconductor encapsulation materials, hole-filling resins, part-embedding resins, and fiber-reinforced composite materials.

1. A resin composition comprising:
a bismaleimide compound (A) including a constituent unit represented by the following Formula (1) and maleimide groups at both ends of a molecular chain;
at least one resin or compound (B) selected from the group consisting of a maleimide compound other than the bismaleimide compound (A), a cyanic acid ester compound, a benzoxazine compound, an epoxy resin, a carbodiimide compound, and a compound having an ethylenically unsaturated group; and
a photocuring initiator (C): 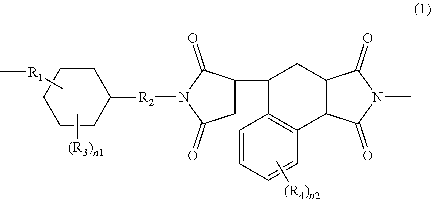
(in Formula (1), R₁ indicates a linear or branched C1-C16 alkylene group or a linear or branched C2-C16 alkenylene group, R₂ indicates a linear or branched C1-C16 alkylene group or a linear or branched C2-C16 alkenylene group, R₃'s each independently indicate a hydrogen atom, a linear or branched C1-C16 alkyl group, or a linear or branched C2-C16 alkenyl group, R₄'s each independently indicate a hydrogen atom, a linear or branched C1-C6 alkyl group, a halogen atom, a hydroxy group or a linear or branched C1-C6 alkoxy group, n₁'s each independently indicate an integer of 1 to 4, and n₂'s each independently indicate an integer of 1 to 4).

2. The resin composition according to claim 1,
wherein the photocuring initiator (C) contains a compound represented by the following Formula (2): 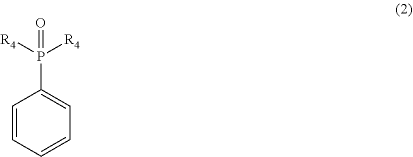
(in Formula (2), R₄'s each independently indicate a substituent or phenyl group represented by the following Formula (3)), 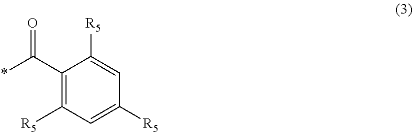
(in Formula (3), -* indicates a bond, and R₅'s each independently indicate a hydrogen atom or a methyl group).

3. The resin composition according to claim 1,
wherein a content of the bismaleimide resin represented by Formula (1) with respect to a total amount of 100 parts by mass of the bismaleimide compound (A), the resin or compound (B) and the photocuring initiator (C) is 5 to 99.4 parts by mass.

4. The resin composition according to claim 1, further comprising a filling material.

5. A cured object comprising the resin composition according to claim 1.

6. A resin sheet, comprising:
a support; and
a resin layer that is disposed on one surface or both surfaces of the support,
wherein the resin layer contains the resin composition according to claim 1.

7. The resin sheet according to claim 6,
wherein the resin layer has a thickness of 1 to 50 μm.

8. A prepreg comprising:
a substrate; and
the resin composition according to claim 1 that is impregnated into or applied to the substrate.

9. A metal-clad laminate comprising:
a layer containing at least one selected from the group consisting of a resin sheet and a prepreg; and
a metal foil that is provided on one surface or both surfaces of the layer,
wherein the layer contains a cured object of the resin composition according to claim 1,
wherein the resin sheet comprises: a support; and a resin layer that is disposed on one surface or both surfaces of the support, wherein the resin layer contains the resin composition, and the resin layer has a thickness of 1 to 50 μm,
wherein the prepreg comprises: a substrate; and the resin composition that is impregnated into or applied to the substrate.

10. A multilayered printed wiring board comprising:
an insulating layer; and
a conductor layer that is formed on one surface or both surfaces of the insulating layer,
wherein the insulating layer contains the resin composition according to claim 1.

11. A sealing material comprising the resin composition according to claim 1.

12. A fiber-reinforced composite material comprising the resin composition according to claim 1 and a reinforcing fiber.

13. An adhesive comprising the resin composition according to claim 1.

14. A semiconductor device comprising the resin composition according to claim 1.
